(19) United States
(12) Patent Application Publication
(10) Pub. No.: US 2011/0001474 A1
(43) Pub. Date: Jan. 6, 2011

(54) NMR INSTRUMENTATION AND FLOW METER/CONTROLLER METHODS AND APPARATUS

(75) Inventors: Charles E. Miller, Boulder, CO (US); John C. Price, Longmont, CO (US)

Correspondence Address: COCHRAN FREUND & YOUNG LLC, 2026 CARIBOU DR, SUITE 201, FORT COLLINS, CO, 80525, US

(73) Assignee: CEMA TECHNOLOGIES, LLC, Boulder, CO (US)

(21) Appl. No.: 12/635,697

(22) Filed: Dec. 10, 2009

Related U.S. Application Data
(63) Continuation-in-part of application No. 12/498,245, filed on Jul. 6, 2009, now abandoned.

(51) Int. Cl. G01R 33/44

(52) U.S. Cl. 324/306

(57) ABSTRACT

Methods and apparatus for obtaining NMR signals from a flowing fluid include permanent magnet assemblies for producing magnetic fields for NMR applications and instrumentations, including, but not limited to, flow metering.

### CROSS-REFERENCES TO RELATED APPLICATIONS

This application is a continuation-in-part of U.S. patent application Ser. No. 12/498,245, filed Jul. 6, 2009, which is incorporated herein by reference.

### BACKGROUND OF THE INVENTION

1. Technical Field

This invention is related to nuclear magnetic resonance (NMR) instrumentation apparatus and methods for use in flow meters and flow controllers as well as in other analytical applications.

2. State of the Prior Art

Nuclear magnetic resonance (NMR) for use in flow measurements, dedicated flow meters, and various analytical measurements on fluids has been investigated extensively, including myriad variations in apparatus and methods of implementation, since at least as early as the 1960s (see, for example, U.S. Pat. No. 3,419,795, issued to Genthe et al.). There are a number of potential advantages of fluid flow measurement by NMR, including the following: (i) NMR does not require disturbing flow of the fluid; (ii) NMR does not require creation of a pressure drop in the flowing fluid; (iii) There are no moving parts; (iv) No instruments or sensors have to be exposed to the flowing fluid other than the inside surface of the flow channel. Therefore, deleterious effects on flow, accuracy, and flow sensor components due to deposits, clogging, abrasion, and fouling by corrosive, abrasive, viscous, or biphase fluids such as slurries can be avoided.

In general, NMR flow meters work on variations of the concept of applying a radio frequency (RF) field to a flow of materials that have a nuclear magnetic moment, usually from an odd number of protons in their atomic structure, for example, hydrogen, fluorine, chlorine, and others, to sense resonance interaction between an externally applied magnetic field and the magnetic moments of the flowing material. Since hydrogen has a large nuclear magnetic moment and is present in high number densities in nearly all fluids, NMR flow meters should be particularly well-suited to hydrogenous materials, including water, hydrocarbons, and many others. Most schemes for measuring flow with NMR principles can be categorized loosely into several groupings, including relaxation methods, time-of-flight methods, and field gradient methods.

NMR flow measurement techniques using relaxation methods generally include the fluid entering and flowing through a region of an external magnetic field for a time before entering a region of an RF coil. During travel time of the fluid in the external magnetic field, the fluid is exposed to the external magnetic field and becomes magnetized more or less according to whether the travel time, thus exposure time, is long or short compared to the time it takes for the magnetic nuclei of the fluid to come into a equilibrium in the external magnetic field (often called the relaxation time T₁). Free induction decay (FID) in response to the RF excitation of the magnetized fluid in the magnetic field produces a signal in a coil, the oscillation amplitude of which is proportional to the degree of magnetization and will vary with flow velocity ν. A pervasive issue in the relaxation method, as in nearly all NMR instrumentation applications, is that the external magnetic field has to be very uniform in the region of the RF coil and FID response in order to obtain useful NMR signals, and obtaining such uniform magnetic fields is a demanding design criterion that has generally required large, heavy, and expensive magnets.

Besides the uniform field requirement, relaxation methods typically have at least two other major drawbacks: (1) They are sensitive over a relatively small flow range, because the maximum sensitivity occurs where the flow velocity ν is approximately equal to the length of travel of the fluid divided by the relaxation time T₁, which is a condition that can only be changed by changing the geometry of the flow measuring system components; and (2) The sensitivity depends strongly on the relaxation time T₁, so that accurate measurements depend on knowledge of the relaxation time T₁ or separate calibration for each fluid.

In time-of-flight methods, a discrete portion of the fluid is tagged magnetically in some manner at a first location, and the arrival of the tagged portion at a second, downstream location is sensed. See, for example, U.S. Pat. No. 3,419,795, issued to Genthe et al. The “time-of-flight” of the tagged portion of the fluid from the first location, where it is tagged, to the second location, where the tagged portion is sensed, is related to velocity of the flow. Of course, flow rate can be determined from velocity of flow in a known flow conduit geometry (e.g., size and shape).

In some “time-of-flight” methods, the fluid enters a magnetic field region and becomes partially or fully magnetized before it reaches a first coil, where a 90° pulse suppresses the magnetization in the direction of the field. After a delay time τ, another 90° pulse in a second coil downstream from the first coil can be used to measure the magnetization there. The arrival of the tagged fluid, i.e., the portion of the fluid with the suppressed magnetization, at the second coil is manifested by a decrease in the amplitude of the NMR signal. In other words, the NMR signal amplitude from the free induction decay (FID) in the proximity of the second coil will have a minimum value indicating the suppressed magnetization, when the time τ between the first and second pulses is equal to the length L of the flow path between the two coils divided by the flow velocity ν, i.e., τ=L/ν. Consequently, the time delay τ between successive first and second pulse pairs can be varied iteratively until a minimum NMR signal amplitude is found, and that time delay τ can be used to calculation flow velocity ν by τ=L/ν.

These kinds of time-of-flight methods do not have to be calibrated for different values of T₁ (relaxation time), although they become insensitive if L/ν is greater than T₁, because the fluid will re-magnetize during the delay time τ, which would effectively eliminate the suppressed magnetization with which the portions of the fluid are tagged before they reach the second coil. It would also be insensitive if the time available for magnetization before the fluid reaches the first coil is substantially less than the relaxation time T₁, because without sufficient pre-magnetization of the fluid, the first coil would not be able to create the tag with the RF frequency, i.e., the suppressed magnetization, in a portion of the flowing fluid.

While such time-of-flight methods have some advantages, the requirement that L/ν should be less than the relaxation time T₁ is difficult to satisfy, especially for low flow rates. Also, the highly uniform magnetic field has to span both coils. Therefore, that requirement for a uniform magnetic field spanning not just one, but two coils is even more difficult to achieve and requires even larger magnets than methods that need only one coil at one location along the flow path.

In field gradient methods, the nuclear spins of the flowing fluid material are aligned using a transverse magnetic field with a linear gradient in which the strength or intensity of the magnetic field either increases or decreases along the flow path. As in other NMR instrumentation techniques, radio frequency (RF) pulses at the magnetic resonant frequency of the material are applied briefly to rotate the magnetic moments relative to the transverse magnetic field, thereby suppressing the magnetization of the fluid that is in the direction of the transverse magnetic field. Since frequency of the magnetic moments is a function of the strength of the external transverse magnetic field, and since there is a gradient in the strength of the transverse magnetic field, only a narrow slice of the flowing material will have its resonant frequency attuned to the RF pulse, i.e., that narrow slice of material that is located where the magnetic field intensity causes magnetic moment frequency that matches the frequency of the RF pulse. After the termination of the RF pulse, the time varying magnetic fields of the spins of the nuclei (FID) are detectable in the RF sensing coil, i.e., the NMR signal, for a short time as they realign to the external transverse magnetic field. However, as the excited slice of the material flows downstream into portions of the gradient external transverse magnetic field that have different magnetic field intensities, the frequencies of the signal emitted by the nuclei change proportionately as they continue to realign with the transverse magnetic field. The intensity of the NMR signal indicates the number of nuclei realigning with the transverse magnetic field, and the combination of signal time delay relative to the RF pulse and the signal frequency indicates the particle velocity. The indicated particle velocity along with the known geometry of the flow path can be used to determine fluid flow rate of the fluid.

Variations of the field gradient methods may include use of phase gradients and frequency gradients. A phase gradient is applied after RF excitation but before the NMR signal is recorded. The pulse establishes a correlation between the precession phase of a group of spins and their position along the direction of the field gradient, i.e., along the flow path. A frequency gradient is applied while the NMR signal is recorded, which establishes a correlation between the recorded precession frequency of a group of spins and their position along the direction of the field gradient, i.e., along the flow path. This information along with time can be used to establish velocity and, with flow path geometry, to establish flow rate of the fluid.

These field gradient methods for fluid flow measurement require not only accurate controls of the field gradient, but also homogeneity of the field along the gradient, which is very demanding on the external magnet characteristics. Meeting such demands generally requires the use of a large and heavy, high quality magnet, the size and cost of which is incompatible with a compact, turnkey, general purpose flow meter.

Consequently, while NMR principles are well known and myriad NMR flow meter apparatus and methods have been tried and even shown to work, the goal of compact, turnkey NMR based flow meters that have and retain accuracy and reliability over a wide range of flow rates, including very low flow rates, as commercial products has remained illusive. In spite of the potential advantages and applications of NMR to flow metering and flow controlling, such instruments are not available in the market due at least in part to the cost and complexity of suitable magnets, RF electronics, signal processing hardware, calibration issues, and other problems.

The foregoing examples of related art and limitations related therewith are intended to be illustrative and not exclusive, and they do not imply any limitations on the inventions described herein. Other limitations of the related art will become apparent to those skilled in the art upon a reading of the specification and a study of the drawings.

### BRIEF DESCRIPTION OF THE DRAWINGS

The accompanying drawings, which are incorporated herein and form a part of the specification, illustrate some, but not the only or exclusive, example embodiments and/or features. It is intended that the embodiments and figures disclosed herein are to be considered illustrative rather than limiting.

In the drawings:

FIG. 1 is an isometric view of an example flow meter/controller utilizing the NMR instrumentation techniques and other features described herein, with portions of the housing cut away to reveal portions of the magnet frame and circuit boards;

FIG. 2 is an isometric view of the magnet frame of the example flow meter in FIG. 1;

FIG. 3 is a side elevation view of the magnet frame in FIG. 2 with an analytical magnet visible in the view;

FIG. 4 is a cross-sectional view of the magnet frame and pre-magnetizer magnets taken along section line 4-4 in FIG. 3;

FIG. 5 is a cross-sectional view of the magnet frame and analytical magnets taken along section line 5-5 in FIG. 3;

FIG. 6 is an isometric view of the pre-magnetizer magnets, analytical magnets NMR flow tube, and RF coil in the example flow meter in FIG. 1, wherein a portion of one of the analytical magnets is cut away to reveal the NMR flow tube and coil in relation to the magnetic;

FIG. 7 is a side elevation view of the magnets;

FIG. 8 cross-section view of the pre-magnetizer magnets taken along section line 8-8 in FIG. 7;

FIG. 9 cross-section view of the analytical magnets taken along section line 9-9 in FIG. 7;

FIG. 10 is a diagrammatic view of an example iron-yoked magnet;

FIG. 11 is a diagrammatic view of an example Halbach cylinder magnet;

FIG. 12 is a diagrammatic view of an example segmented Halbach cylinder magnet;

FIG. 13 is a diagrammatic view of another segmented Halbach cylinder magnet;

FIG. 14 is an idealized diagrammatic view of a longitudinal cross-section of the NMR sample tube and RF coil with magnetized fluid flowing through the tube;

FIG. 15 is an idealized diagrammatic view similar to FIG. 14, but after a RF 90° pulse has been applied to the magnetized fluid in the coil volume;

FIG. 16 is an idealized diagrammatic view similar to FIG. 15, but after the fluid that was excited has partially passed out of the coil volume and been replace by fresh, magnetized fluid;

FIG. 17 is an idealized diagrammatic view similar to FIG. 16, but after the fresh, magnetized replacement fluid has had the second 90° pulse applied;

FIG. 18 is an idealized diagrammatic view similar to FIG. 15, but after the previously excited fluid has passed completely, not just partially, out of the coil volume;

FIG. 19 is an idealized diagrammatic view similar to FIG. 18, but after a RF 90° pulse has been applied to the magnetized fluid in the coil volume;

FIG. 20 is a typical free induction decay (FID) signal beginning immediately after a magnetized fluid has been excited with a RF 90° pulse;

FIG. 21 is a graphical illustration of the dependence of the FID amplitude ratio R on flow velocity ν;

FIG. 22 is a schematic circuit diagram of an example circuit for driving and receiving FID signals from the coil;

FIG. 23 shows an example first FID signal from a magnetized fluid flowing through the coil volume that has been excited with a RF 90° pulse and an example second FID signal from fluid in the coil volume that has been excited a second time with a second RF 90° pulse after a delay time τ has allowed depleted fluid in the coil volume to be partially replaced by fresh, magnetized fluid;

FIG. 24 shows example first and second FID signals similar to FIG. 23, but after a very short delay time τ that simulates the signals from a fluid that is virtually stationary;

FIG. 25 shows graphically the relationship of the FID amplitude ratio R to flow rate for an actual sample fluid;

FIG. 26 shows graphically the relationship of the FID amplitude ratio R to flow rate for an actual sample fluid in four different but overlapping flow rate ranges;

FIG. 27 shows graphically the one-sigma flow repeatability computed from the data in FIG. 26;

FIG. 28 shows a graphical representation of idealized strength of the RF magnetic field generated by a RF pulse in the coil volume;

FIG. 29 shows a graphical representation similar to FIG. 28, but for more realistic (not necessarily actual) conditions;

FIG. 30 shows a graphical representation similar to FIGS. 28 and 29, but for a modified coil;

FIG. 31 is a diagrammatic representation of the magnetic field generated by a coil;

FIG. 32 is a diagrammatic representation of the magnetic field generated by a modified coil as shown in FIGS. 33 and 34;

FIG. 33 is a diagrammatic view of a modified coil with reversed loops at its ends;

FIG. 34 is a diagrammatic view of the modified coil of FIG. 33 on a NMR sample flow tube illustrating the reverse flow of electric current in the end loops;

FIG. 35 is an idealized diagrammatic view of a longitudinal cross-section of the NMR sample tube and RF coil illustrating inverted nuclear magnetic moments after a RF 180° pulse has been applied to the magnetized fluid in the coil volume;

FIG. 36 is an idealized diagrammatic view similar to FIG. 35, but after one half of the coil volume has been refilled by fresh, magnetized fluid; and

FIG. 37 is an idealized diagrammatic view similar to FIG. 36, but after a RF 90° pulse has been applied to both the fresh, magnetized fluid in one-half of the coil volume and the inverted magnetized fluid in the other half of the coil volume.

### DETAILED DESCRIPTION OF EXAMPLE IMPLEMENTATIONS

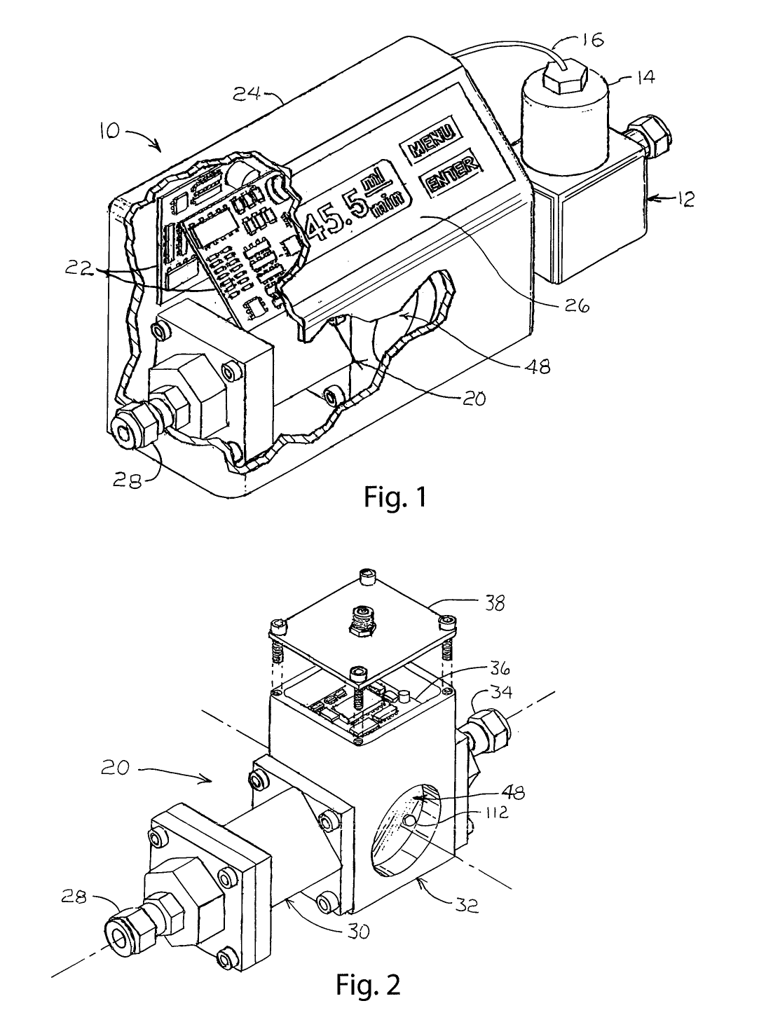

An example NMR flow meter/controller 10 is shown in FIGS. 1-9 to illustrate NMR instrumentation techniques and apparatus improvements that alone and/or in combination can improve, reduce costs, and make NMR instrumentation and analytical capabilities more available, convenient, and cost effective for a variety of fluid applications. Therefore, while most of the description herein utilizes the example flow meter 10 as a convenient vehicle to explain the features, apparatus, and methods claimed herein, these features, apparatus, and methods are not intended to be limited to this example or to only flow meters or flow controllers. On the contrary, NMR signal generation and detection using any one or more of the features or processes described herein are useful for myriad other NMR instrumentation and analytical applications as well. Also, the illustrations in the drawings are not drawn to illustrate any particular sizes or proportions, and while some such sizes or proportions may be exaggerated or distorted for practicality, persons skilled in the art will understand the information illustrated.

With those understandings, references are now directed initially to FIGS. 1-9. The example flow meter 10 is illustrated in FIG. 1 with a standard control valve 12 connected to its outflow end to show the flow meter 10 in a flow controller assembly. Flow controller valves and control actuators are well known and readily available commercially, and persons skilled in the art know how to install and use them with signals from flow meters of all kinds to control fluid flows, so no further description or explanation of the control valve 12 is needed here. Suffice it to say that the flow control valve 12 can be used in conjunction with any flow meter, including the example NMR flow meter 10 described herein, to control the flow of fluid through the flow meter 10 or elsewhere in a particular application with control signals based on flow measurements by the flow meter. In the example illustrated in FIG. 1, the control valve 12 is shown connected to the outflow connector of the flow meter 10, and a control valve actuator 14 on the control valve 12 is shown connected by a suitable cable or wires 16 to the flow meter 10, which can imply that the control signals for the control valve actuator 14 are produced by the electronics in the flow meter 10, although they can be produced externally or by electronics in the control valve package itself or elsewhere, depending on the sophistication of the control valve package used. Generally, flow control electronics, software, and/or firmware can be set to a desired flow rate, and signals from the flow meter that are indicative of actual flow rate are compared to the desired flow rate, and, if different, control signals are sent to the control valve actuator 14 to increase or decrease the opening in the control valve 12 until the flow meter 10 measurements show that the actual flow rate matches the desired flow rate, all of which is well understood by persons skilled in the art.

In the example flow meter 10 in FIGS. 1-9, the frame structure or casing 20 that contains the magnet assemblies 44, 48 and coil 60 (not seen in FIGS. 1 and 7) for nuclear magnetic resonance (NMR) excitation and detection in a fluid, and associated electronic components on one or more circuit boards 22 are shown packaged in a housing 24 (FIG. 1), although they can be positioned anywhere, including remote locations or central control stations. A display and control panel 26 is shown, for example, mounted in the housing 24. Again, these illustrations are for example only. The NMR components described herein can be configured, packaged, and located in any number of ways by persons skilled in the art, once they understand the principles described herein.

The example framework or casing 20 shown in FIGS. 2-5 (without the housing 24) mounts and retains the magnet assemblies 44,48 and NMR flow tube 40 components, which are described in more detail below. A fluid to be measured or analyzed by NMR flows into the inflow connector 28 shown in FIGS. 2-5, through a pre-magnetizer section 30, where the fluid is initially magnetized, then through an analyzer section 32, where the magnetization of the fluid is homogenized and the magnetized fluid is excited by the coil 60 to produce and detect an NMR signal, as will be described in more detail below, and then the fluid flows out of the outflow connector 34. The pre-magnetizer section 30 contains the pre-magnetizer magnet assembly 48, and the analytical section 32 contains the analytical magnet assembly 48 and RF coil 60, which will also be described in more detail below. An electronic circuit board 36 with electronics to drive the coil 60 and detect the NMR signal is shown mounted in the analyzer section 32 of the casing 20 and covered by a shield 38, but those electronics could be located anywhere.

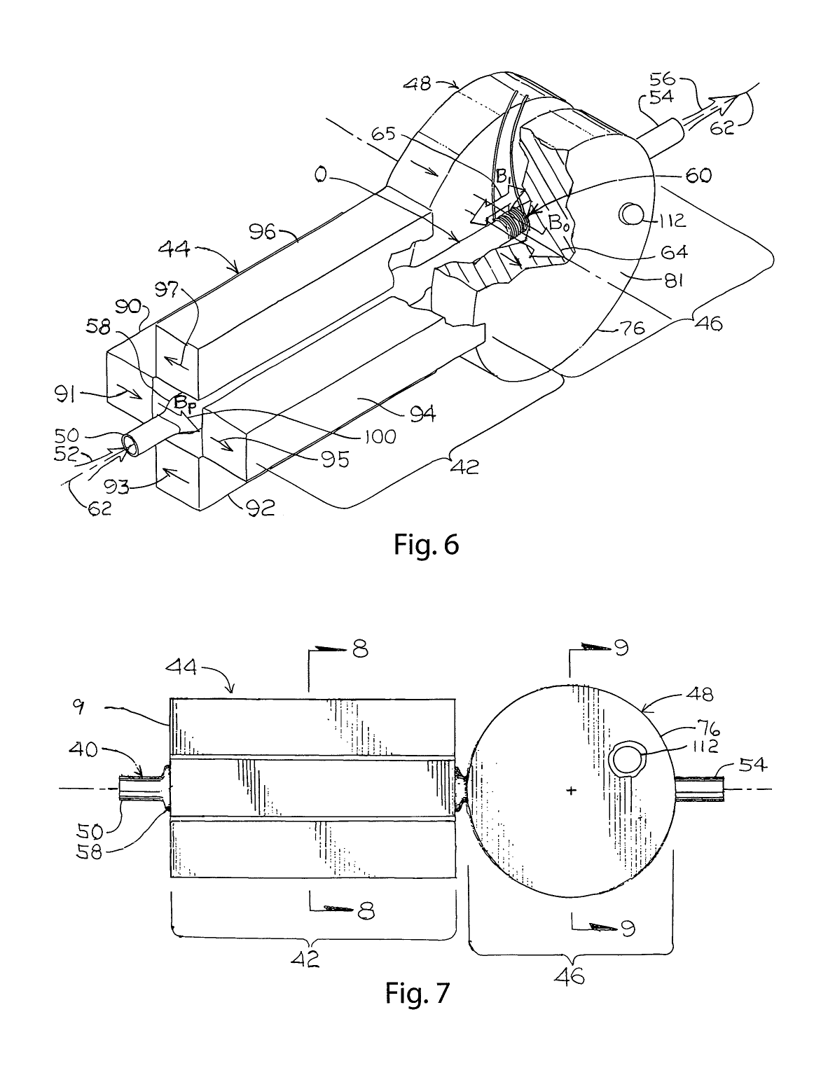

With reference now primarily to FIGS. 6-9, the pre-magnetizer and analytical magnet assemblies 44,48, NMR sample flow tube 40, and coil 60 are illustrated without the mounting frame and peripheral components for simplicity and clarity. The NMR sample tube 40 extends through a pre-magnetizer zone 42 created and surrounded by the pre-magnetizer magnet assembly 44 and through an analytical magnet zone 46 created and surrounded by the analytical magnet assembly 48. The fluid flows into the inflow end 50 of the NMR sample tube 40, as indicated by the flow arrow 52, through the pre-magnetizer zone 42 and then through the analytical magnet zone 46, and then out of the outflow end 54, as indicated by the flow arrow 56. The NMR sample tube 40 can be comprised of any suitable non-magnetic material that can contain and is compatible with the fluid, and that does not interfere with the applied RF fields induced and detected by the coil 60 as described below. Thin walls are usually better than thick walls so that the fluid fills a large fraction of the volume of the space surrounded by the coil 60 in order to create a strong NMR signal. Silicate glasses and various polymers (e.g., perfluoroalkoxy known as PFA) are examples of suitable tube materials for containing many fluids. Tube size can vary depending on intended flow rate ranges, pressure drop parameters, magnetic field strengths, and other factors considered or desired in particular applications and designs, as will be understood by persons skilled in the art.

An optional larger cross-section tube portion 58 can be used, if desired, in the pre-magnetizer zone 42, if longer dwell time of the fluid in the pre-magnetizer zone 42 is desired for more complete pre-magnetization of the fluid before it enters the analytical zone 46. This option may be useful, for example, in flow meters designed for measuring high flow rates in order to provide sufficient time in the pre-magnetization zone. Of course, a longer pre-magnetization zone 42 could also be used to get more complete pre-magnetization of the fluid, but a longer pre-magnetization zone 42 would require a longer pre-magnetizer magnet assembly 44, which is much more bulky and more expensive than a larger cross-section pre-magnetizer tube portion 58. Another option to increase pre-magnetization of the fluid with a given pre-magnetization field is to provide a tube 40 with a circuitous path (not shown) through the pre-magnetization zone 42 to increase dwell time of the fluid in the pre-magnetization zone 42, although a circuitous flow path may be more difficult to provide in a compact system.

As best seen in FIGS. 6 and 9, an RF coil 60 of electrically conductive wire is positioned around the NMR sample tube 40 in the analytical zone 46. In general, the analytical magnet assembly 48 provides a static magnetic field B₀ as spatially uniform in strength or intensity throughout the analytical magnetic zone 44 as practical, especially in the proximity of the coil 60, and aligned generally transverse to the longitudinal axis 62 of the tube 40, as indicated by the magnetic field vector arrow 64. The RF coil 60 is oriented and positioned to produce an alternating magnetic field B₁ orthogonal to the direction 64 of the static magnetic field B₀ when the coil 60 is activated with a radio frequency (RF) alternating current (AC) signal from an RF signal generator (not shown in FIGS. 6 and 9). When the wire of the coil 60 is wrapped or coiled around the sample tube 40 as shown in FIGS. 6 and 9, the alternating magnetic field B₁ is produced in the direction of the longitudinal axis 62 of the sample tube 40, as indicated by the arrow 65 for the RF field B₁ in FIG. 6. While not shown in FIGS. 6 and 9, the RF coil 60 could be positioned and oriented to apply the alternating magnetic field orthogonal to both the static magnetic field direction 64 and flow tube axis 62, if desired. Either way, the alternating magnetic field produced by the coil 60, when applied at an appropriate frequency and for appropriate time duration, as explained in more detail below, causes suppression of the magnetization of the nuclear magnetic moments or spins of the protons in the fluid that was induced by the static magnetic field of the analytical magnet assembly 48 in the direction 64 and imposes coherent precession of the spins or nuclear magnetic moments about the direction of the static magnetic field B₀. The alternating magnetic field B₁ causes such suppression by rotating the nuclear magnetic moments to precess coherently (i.e., in phase with each other), or nearly so, in a plane orthogonal to the direction 64 of the static analytical magnetic field B₀. Since it is not possible physically to provide a perfectly homogenous analytical magnetic field B₀, variations in the intensity of the analytical magnetic field B₀ at different spatial locations in the field cause nuclear magnetic moments at different locations in the field B₀ to precess at different frequencies. Therefore, it is important for the analytical magnetic field B₀ to be as homogenous, i.e., uniform spatially, as practical in order for the precessing nuclear magnetic moments to be as nearly coherent as practical.

Such coherent or nearly coherent precession of the nuclear magnetic moments of the fluid immediately after the pulse of alternating magnetic field stops, induces a detectable voltage, i.e., the NMR signal, in the coil 60 (or in any other coil in proximity to the excited fluid). However, a number of factors, including inhomogeneity of the analytical magnetic field B₀, which cause different nuclear magnetic moments to precess at different angular velocities, thus less than perfectly coherent precessions of nuclear magnetic moments, result in rapid dephasing of the precessing nuclear magnetic moments. Such dephasing limits the duration of the free induction decay (FID) and causes the amplitude of the NMR signal detected in the coil 60 to decrease. The less homogenous the static field B₀ is, the weaker the NMR signal will be, and the faster it will decay or disappear.

It may be helpful to mention here that the terms nuclear magnetic moments, nuclei magnetic moments, and spins are sometimes used interchangeably. Also, the NMR signals obtained from free induction decay (FID) detected by the coil 60 are also sometimes called FID signals, or just FID, and these terms may be used interchangeably when the free induction decay FID provides the NMR signal being used. However, NMR signal can also be obtained from spin-echo, which is not solely free induction decay, so, in a sense, NMR signal is a broader term in that it can be derived from FID, echo, or other nuclear magnetic resonance effects.

For the reasons mentioned above, it is important for the analytical magnetic field B₀ to be as spatially uniform or homogenous as practical in order to get useful NMR signals. While a number of different magnet configurations and combinations have been used to provide uniform magnetic fields for various NMR applications and can be used with the NMR flow metering methods and techniques described herein, there are drawbacks associated with some of them. For example, iron-yoke dipole magnets, such as the iron-yoke dipole magnet assembly 66 shown diagrammatically in FIG. 10, are readily available commercially and provide fairly uniform magnetic fields. Such iron-yoke dipole magnet assemblies may comprise, for example, two disk-shaped NdFeB or SmCo magnets 68, 70 with or without soft magnetic pole faces. The ferromagnetic yoke 72, usually iron, that couples the two magnets 68, 70 and provides a return path for the magnetic field, is typically either C-shaped or a box open on two sides as illustrated in FIG. 10. Typical outside dimensions of conventional iron-yoke dipole magnets that are suitable for NMR instrumentation applications, such as those described herein, e.g., proton Larmor frequencies in a range of about 10-30 MHz, are about six inches per side. Therefore, they are satisfactory for at least some of the NMR techniques and applications described herein, although they are more bulky and massive than desired for smaller, turnkey commercial NMR instruments, such as flow meters, especially for small, low flow rate flow meters.

Halbach magnets, such as the cylindrical Halbach magnet in FIG. 11 with a continuously varying direction of magnetization, or the segmented Halbach magnet assemblies shown in FIGS. 12 and 13, which use assembled individually magnetized wedges to approximate the continuously varying direction Halbach magnet in FIG. 11, can also provide fairly uniform fields at their centers. However, the Halbach cylinder arrangement of FIG. 11 with continuously varying magnetization direction is difficult to manufacture, and the wedge assemblies in FIGS. 12 and 13 are difficult to design, magnetize, and assemble for a uniform field and may not have enough strength for particular NMR applications. None of the magnets shown in FIGS. 10-13 have been particularly attractive, useful, or practical for small, compact, turnkey flow meter or flow controllers because of weight, bulk, strength, design, assembly, cost, and other issues, although they can be used for some of the methods and implementations described herein. In the depictions of magnet assemblies in FIGS. 6-13, the small arrows indicate the orientation of the magnetization of each individual piece or area of magnetic material, and the larger arrows show the overall composite magnetic field of the assembly.

An example small, compact magnet system that provides a highly uniform analytical magnetic field B₀ that is strong enough for NMR flow metering and/or analytical instrumentation for flowing fluids is shown in FIGS. 6-9 supplemented by a pre-magnetizing magnetic field Bₚ. This system includes the pre-magnetizer magnet assembly 44 comprising a Halbach type magnet configuration in combination with an analytical magnet assembly 48 comprising a permanent magnet analog of a Helmholtz magnet configuration, which is sometimes called herein a Helmholtz analog or pseudo-Helmholtz magnet. As mentioned above, in order to obtain an NMR (FID) signal from a fluid, the fluid first has to be magnetized in a highly uniform magnetic field B₀ to induce a collection of identical magnetic moments of atomic nuclei (protons) to come into equilibrium magnetization in the direction of the highly uniform magnetic field B₀. Initially, the nuclear magnetic moments in the fluid are oriented at random. Over time, however, the nuclear magnetic moments come into equilibrium, static average magnetization M₀ develops in the direction of the uniform field, and they precess about an axis oriented in the direction of the uniform field B₀ at a fairly uniform frequency called the Larmor frequency f_{L}, albeit still at random phases. In most cases, such equilibrium magnetization of the nuclear magnetic moments develops exponentially in time, i.e., the magnetization M is a function of time M(t), as follows:

M(t)=M₀(1-exp(−t/T₁)) (1)

where T₁ is a time constant called the energy or spin-lattice relaxation time, because the nuclear magnetic moments or spins give up energy to their environment in order to come to the equilibrium at a lower energy state for the individual nuclear magnetic moments aligned with the uniform field B₀. Sometimes T₁ is simply called the relaxation time T₁ for convenience. T₁ is typically about one second or more for aqueous and other low viscosity solutions. Increasing viscosity is correlated with reduced relaxation time T₁.

This relaxation of the nuclear magnetic moments to an equilibrium state is followed by the excitation of the precessing nuclear magnetic moments with the RF pulse of alternating magnetic field B₁ directed orthogonal to the uniform magnetic field B₀ to impose coherence, i.e., uniform phase, to the precessing nuclear magnetic moments and simultaneously to rotate them away from the relaxed equilibrium orientation to a higher energy precessing orientation in a plane orthogonal to the uniform magnetic field B₀. In that more coherent, higher energy, precessing state, the combined magnetic fields of the coherently precessing nuclear magnetic moments induce the detectable NMR signal in the coil 60, as discussed above.

However, the relaxation time T₁ required for the nuclear magnetic moments to give up their energy and relax to the equilibrium energy state in the direction of the uniform magnetic field B₀ before the RF pulse of alternating magnetic field B₁ is applied, e.g., one second or more, is a long time for the flowing fluid to have to remain in the uniform magnetic field B₀. As discussed above, creating highly uniform magnetic fields is not easy, and it would require a large and complex magnet system to create a long enough, highly uniform, magnetic field B₀ to expose a flowing fluid for a full second or more before the fluid is allowed to flow out of the field B₀. It would have to be done with much larger, bulkier, and more expensive magnet components than is practical or needed for many NMR flow meter or analytical applications.

A very highly uniform magnetic field B₀ is important for the location and proximity of the coil 60, because the precession rate (Larmor frequency f_{L}) of the nuclear magnetic moments in the fluid is directly related to the strength of the magnetic field B₀ by the relationship:

f_{L}=γ/2π·B₀ (2)

where γ is called the gyromagnetic ratio of the magnetic moment to the magnitude of the spin angular momentum. For magnetic moments of hydrogen nuclei (protons), which are present at high concentrations in almost all liquids, the relationship between the Larmor frequency f_{L}, (precession rate of the hydrogen nuclear magnetic moments) is:

f_{L}=42.58 MHz/T·B₀ (3)

where megahertz (MHz) is a unit of frequency meaning 10⁶ cycles per second, and Tesla (T) is a unit of magnetic field meaning one weber per square meter. Therefore, if the magnetic field B₀ could be perfectly uniform or homogenous, all of the hydrogen nuclei in the fluid would precess at exactly the same Larmor frequency f_{L}. On the other hand, the more inhomogeneities there are in the magnetic field B₀(i.e., the less uniform the field is), the more variations there will be in the precession rates of the individual hydrogen nuclear magnetic moments, and as the precessions de-phase, the NMR signal decays and disappears, i.e., the free induction decay (FID). Therefore, the more inhomogeneities there are in the magnetic field B₀, the more rapid will be the de-phasing and resulting decay and disappearance of the FID or NMR signal. As mentioned above, the terms NMR signal and FID signal or FID are sometimes used interchangeably in the art and in this description when discussing the NMR signal from free induction decay.

The interaction energy of a nuclear magnetic moment with any attainable applied magnetic field B₀ is always very small compared to the thermal energy at room temperature, which disorients molecules in the fluid, so the average degree of orientation or polarization of nuclei by the magnetic field B₀ is also very small. Moreover, the nuclear magnetic moment is small, about 2,000 times smaller than the electron magnetic moment responsible for ferromagnetism. Nevertheless, because of the enormous number of protons present in a typical macroscopic sample (e.g., about 10²³), the RF magnetic fields generated by the precessing protons can be detected, provided they are all made to precess at nearly the same frequency and phase, which requires a very uniform magnetic field B₀, as discussed above, in the vicinity where the RF coil 60 is located.

However, while a highly uniform magnetic field B₀ at the location and proximity of the RF coil 60 is important, a less demanding magnetic field can be used for the initial magnetization of the fluid that orients the nuclear magnetic moments to align with the field B₀. Therefore, the pre-magnetizer zone 42 (FIG. 6) is used to provide the initial magnetization of the fluid flowing through the sample tube 40, so that a small-sized, but highly uniform, analyzer magnetic field B₀ can be provided for the location and proximity of the RF coil 60 in the analytical magnet zone 46. Therefore, as shown in FIG. 6, a pre-magnetizer magnet system 44 provides a fairly uniform magnetic field Bₚ, as indicated by the arrow 100 in FIG. 6, although not necessarily as highly uniform as the analytical magnetic field B₀, along a sufficient length of the flow tube 40 to pre-magnetize the fluid in the tube 40 enough so that the highly uniform analytical magnetic field B₀ in the vicinity of the coil 60 can then take over to homogenize the magnetization of the fluid to enable a good NMR signal without having to do the entire task of magnetizing the fluid itself The premagnetizer magnetic field Bₚ does not have to be as highly uniform as the analytical magnetic field B₀, because its function is to do the initial work of orienting the nuclear magnetic moments somewhat in the same direction, so that the analytical magnetic field B₀ with a more highly uniform magnetic field can perform the remaining work of unifying the orientation and precessing frequencies of the nuclear magnetic moments in the fluid at the location coil 60. The pre-magnetizer field Bₚ is shown in FIG. 6 oriented in the same direction 100 as the analytical field B₀ orientation 64 as a way to facilitate maintaining a high level of magnetization of the fluid as it flows from the pre-magnetization zone 42 to the analytical magnet zone 46, although having Bₚ and B₀ oriented in the same direction is not essential.

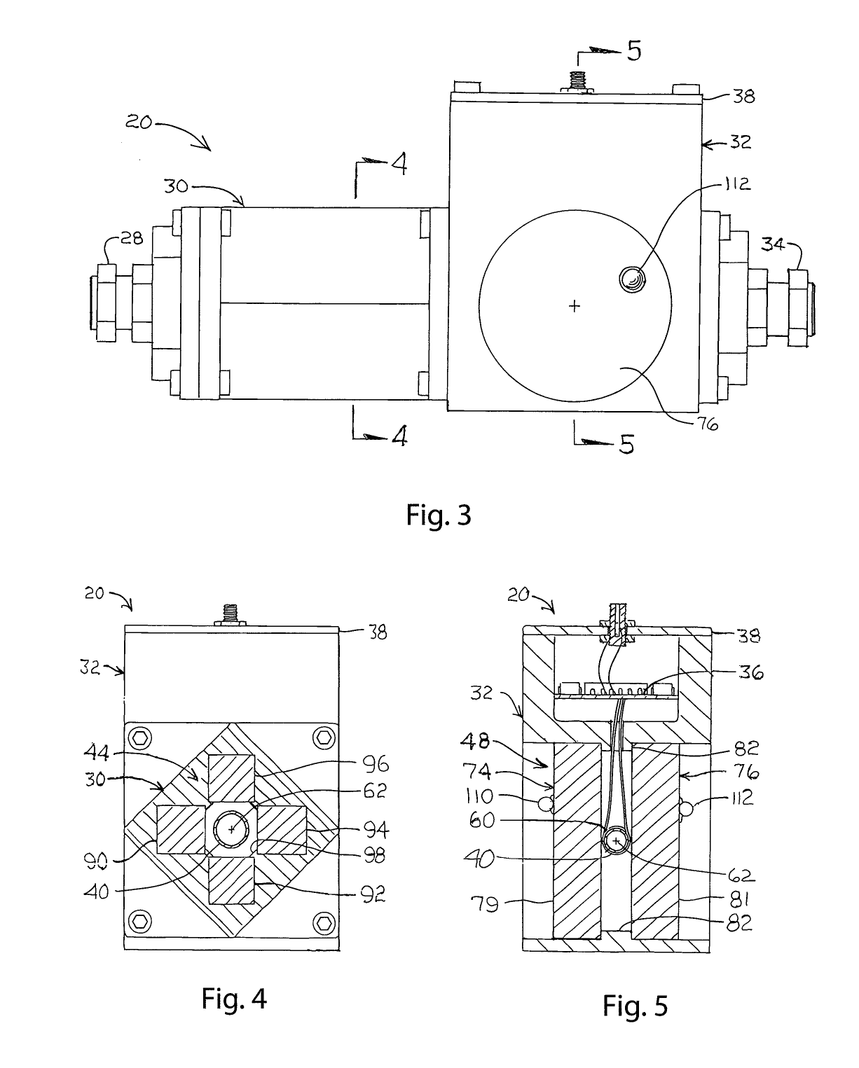

As mentioned above, the uniform magnetic field B₀ for the analytical magnet zone 46 can be provided by any of a number of magnet systems for use in NMR instrumentation and analytical systems and techniques, including those described herein, but the Helmholtz analog or pseudo-Helmholtz analytical magnet assembly 48 shown in FIGS. 3-9 is particularly useful for this example small, compact NMR magnet system described herein. The example analytical magnet assembly 48 is in a sense a permanent magnet analog of a Helmholtz coil pair, which the inventors developed to be small enough, but with a strong enough, large enough, and highly uniform enough magnetic flux density to make the magnet system 48 suitably compact and easy enough to assemble for use for the analytical magnet zone 46 in a compact, turnkey, general purpose flow meter as well as in other analytical and quality control applications.

A conventional Helmholtz coil pair (not shown herein) is known in the art as a set of two identical, circular, co-axial coils spaced apart from each other by a distance equal to the radius of the coils and with equal current flowing through them in the same direction to produce a region of nearly uniform magnetic field at the midpoint between the coils. The magnetic field at the midpoint has linear, quadratic, and cubic dependences on the coordinates all equal to zero or nearly so. The two identical, axially magnetized, co-axial, spaced apart, cylindrical disc permanent magnets 74, 76 of the analytical magnet assembly 48, best seen in FIGS. 5-7 and 9, form a permanent magnet analog to a Helmholtz coil pair, thus is sometimes called herein an analog Helmholtz magnet or pseudo-Helmholtz magnet for convenience. The source for the magnetic field B₀ may be considered as an equivalent current equal to the curl of the magnetization. For a disk uniformly magnetized along its axis, this equivalent current flows around the cylindrical periphery. The equivalent surface current density is given by the remnant magnetization divided by the vacuum permittivity:

J_{S}=Bᵣ/μ₀

For a rare earth NdFeB, J_{S} is in the range of 950 to 1,050 amps per millimeter (A/mm), depending on the grade of material used. With finite thickness disk magnets 74, 76, the first three spatial derivatives can still be made to vanish (this property stems from the high symmetry), but the optimal spacing between the two disk magnets 74, 76 is not necessarily equal to the radius and has to be found numerically or empirically. In general, a higher field B₀ strength results in stronger NMR signals, and, if the disk thickness is increased at constant diameter, the central field B₀ strength increases. However, while increasing the thickness of the disk magnets 74, 76 without changing diameter will increase field strength, it also makes the uniformity of the field decrease, unless the spacing between the juxtaposed inner faces 78, 80 of the disks 74, 76 is decreased. Of course, decreasing the spacing between the disk magnets 74, 76 limits the size of the sample tube 40 and coil 60 that can fit between the two disk magnets 74, 76. Consequently, in order to maintain maximized uniformity of the magnetic field B₀ in a broad area at and around the midpoint where the coil 60 is positioned, a compromise may have to be taken between higher field B₀ strength and keeping enough space between the disks 74, 76 for the sample volume, i.e., the sample tube 60 size, desired. This compromise leads to central magnetic field B₀ values in a range of 0.25 to 0.70 T, or Larmor frequencies 10 to 30 MHz for NdFeB magnet material. Other magnet materials, for example, SmCo (comprising samarium, cobalt, and iron) can also be used, but a SmCo field would not be as high as NdFeB. However, the magnetization of SmCo varies less with temperature changes than the magnetization of the NdFeB material. Consequently, SmCo might be a better choice for a particular application and operating temperature range than NdFeB, even though it provides a lower field strength than NdFeB. The two disks 74, 76 have an attraction toward each other and can be held apart at the desired spacing, for example, by an annular shoulder 82 in the frame 20 (FIG. 5), or by any other suitable structure or spacer. The frame 20 is made of aluminum or other non-magnetic material so that it does not distort or affect the magnetic fields. The disks 74, 76 of the pseudo-Helmholtz magnet assembly can be comprised of several thinner disks (not shown) if desired or convenient to get the desired overall disk thickness.

As mentioned above, the pre-magnetizer magnetic field B₁ does not have to be as highly homogenous or uniform as the analytical magnetic field B₀. It is important, though, that the field of the pre-magnetizer magnet assembly 44, which is positioned in close proximity to the analytical zone 46, will not distort the otherwise highly uniform analytical magnetic field B₀, or at least that such distortion will be minimal. Therefore, the example pre-magnetizer magnet assembly 44 shown in FIGS. 4 and 6-8 is a Halbach-cylinder-based design, albeit somewhat simplified as compared to the more complete Halbach cylinder magnets shown, for example, in FIGS. 11-13, which could also be used, if desired. The Halbach cylinder-type magnet system 44 is used for the pre-magnetizer zone 42 because Halbach cylinder magnet designs have zero or near zero total dipole moment. A Halbach array is characterized by an arrangement of permanent magnets that augments the magnetic field on one side of the array while canceling the field to near zero on the other side. When a Halbach array is arranged in a cylindrical shape and the fields of the respective magnet sections or segments are magnetized as indicated by the small arrows in FIGS. 11-13, the resulting field is almost entirely within the cylinder with zero or near zero field outside the cylinder. Therefore, the exterior field, even if not exactly zero, falls off very rapidly. Consequently, when a Halbach cylinder type of magnet with the magnetized segments or sections directed to produce the magnetic field within the cylinder is used for the pre-magnetizing magnet assembly 44, the distortion of the analytical magnetic field B₀ by the pre-magnetizing magnetic field Bₚ is minimal. Therefore, the analytical magnetic field B₀ produced by the analyzer magnet assembly 48 can be maintained in very uniform condition, even with the Halbach cylinder type pre-magnetizer assembly 44 and its pre-magnetizer field Bₚ positioned in close proximity to the analyzer magnet assembly 48.

As mentioned above, the Halbach cylinder design and configuration of the pre-magnetizer assembly 44 shown in FIGS. 6-8 could be a more complete cylinder, such as the Halbach cylinder magnet cross-sections illustrated in FIGS. 11-13 or other Halbach magnet designs or configurations, but they are complex and difficult to manufacture and assemble. Fortunately, it was found during the development of the magnet systems described herein that the simplified Halbach cylinder design and configuration shown in FIGS. 6-8 for the pre-magnetizer assembly 44 provides a strong enough and uniform enough magnetic field Bₚ to effectively pre-magnetize the fluid flowing through the sample tube 40 so that the highly uniform magnetic field B₀ produced by the pseudo-Helmholtz analytical magnet assembly 48 at and in proximity to the coil 60 results in a good NMR signal and that the pre-magnetizer magnetic field Bₚ produced by this simplified Halbach cylinder design is sufficiently confined to the interior of the assembly 44 and falls off rapidly enough at the exterior of the assembly 44 to have only a minimal effect on the analytical magnetic field B₀ of the pseudo-Helmholtz magnet system 48. Consequently, the uniformity or homogeneity of the analytical field B₀ is maintained at a high level, even in the close proximity to the pre-magnetizer field Bₚ, which is important for producing good NMR signals. Having the premagnetizer field Bₚ in close proximity to the analytical field B₀ is beneficial for maintaining a high level of magnetization of the fluid as it flows from the pre-magnetizer zone 42 to the analytical magnet zone 46, but much of that benefit would be compromised if the pre-magnetizer field Bₚ caused distortions and inhomogeneities in the analytical field B₀. Therefore, the combination of a Halbach cylinder type premagnetizer magnet assembly 44 (which may or may not be the simplified Halbach cylinder configuration in FIGS. 6-8) with an analytical magnet assembly 48 that produces a highly uniform analytical field B₀ (which may or may not include a pseudo-Helmholtz magnet assembly), provides good pre-magnetization of the fluid as well as good NMR signals from a highly uniform analytical magnetic field B₀.

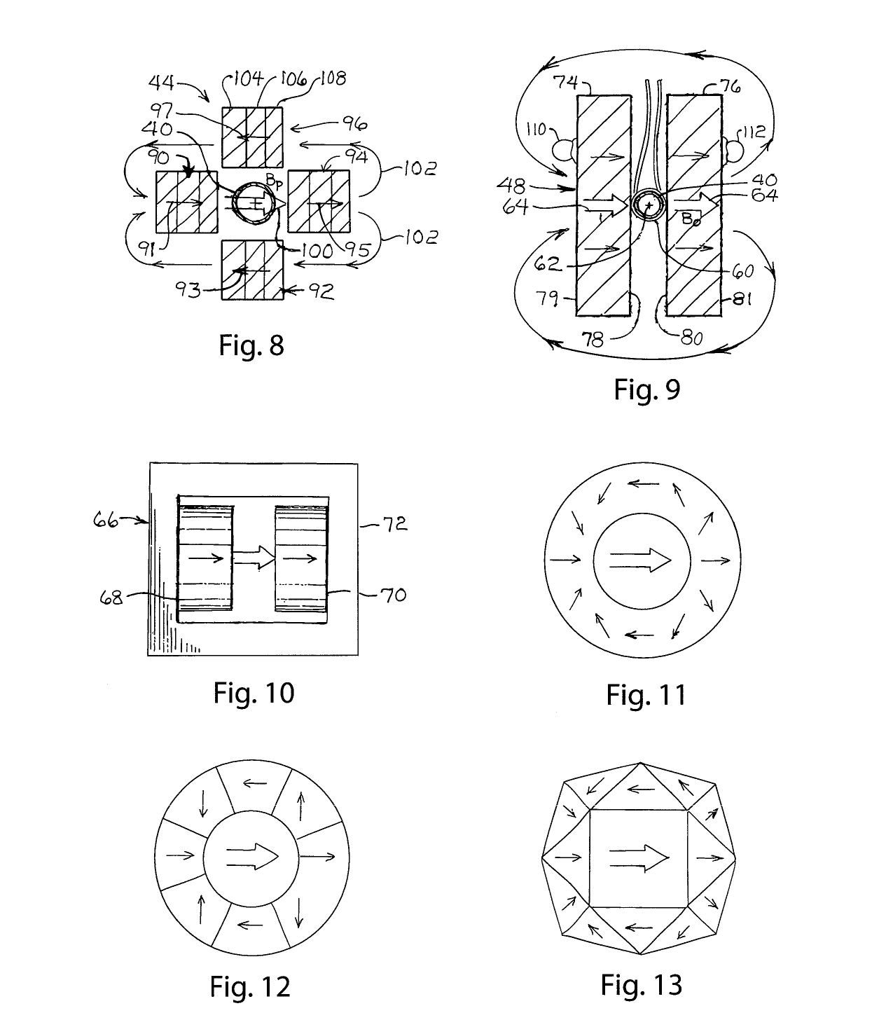

As illustrated in FIGS. 4 and 6-8, the simplified Halbach cylinder arrangement of the pre-magnetizer magnet assembly 44 comprises four elongated bar magnets 90, 92, 94, 96 magnetized as indicated by the small arrows 91, 93, 95, 97, respectively, and assembled in a cross configuration in cross-section in order to create an approximate Halbach cylinder effect. It is helpful to position the bar magnets 90, 92, 94, 96 tightly in the cross configuration with adjacent corners of the respective bar magnets 90, 92, 94, 96 as close to touching each other as practical, given the physical constraints of a suitable mounting structure 98 (FIG. 4) in the frame 20, in order to simulate a Halbach cylinder and maximize confinement of the magnetic field to the interior of the assembly 44, as indicated by the large field arrow 100 in FIG. 8, with minimal external field 102.

If desired or convenient, each bar magnet 90, 92, 94, 96 can be a composite or assembly of several smaller bar magnets, as illustrated in the cross-section of FIG. 8, where, for example, the bar magnet 96 is comprised of three smaller bar magnets 104, 106, 108. (The example small bar magnets comprising the bar magnets 90, 92, 96 in FIG. 8 are not numbered in order to avoid unnecessary clutter in the drawing.)

Besides being much smaller and lighter than a conventional yoked magnet assembly, the pseudo-Helmholtz configuration and design for the analytical magnet assembly 48 shown in FIGS. 3, 5-7, and 9 leaves exposed external surfaces 79, 81, which facilitate shimming the disk magnets 74, 76, as needed, to minimize or eliminate inhomogeneities in the analytical magnetic field B₀. For example, the disk magnets 74, 76 are shown in FIGS. 3, 5-7, and 9 shimmed with steel balls 110, 112 on their external surfaces 79, 81, respectively. As also shown, for example, in FIGS. 1-3 and 5, the disk magnets 74, 76 can be mounted in a frame 20 or other structure in a manner that makes their external surfaces 79, 81 accessible in their mountings, so that they can be shimmed while mounted.

The shimming process can be done empirically or with the aid of a magnetic field mapping tool and a software program for computation of magnetic fields. Myriad software programs for computing magnetic fields from geometries and properties of magnets are available commercially and well-known to persons skilled in the art, for example, RADIA, available from the European Synchrotron Radiation Facility (ESRF), Grenoble, France. For example, a Hall magnetometer can be inserted into the space between the disk magnets 74, 76 (e.g., before the sample tube 40 and coil 60 are mounted) and used to measure and map the field B₀ of the pseudo-Helmholtz analytical magnet assembly 48 (with or without the Halbach pre-magnetizer magnet assembly 44) and to find inhomogeneities in the analytical magnetic field B₀ in the vicinity where the coil 60 is located or will be located. Various positions of the Hall magnetometer between the magnet disks 74, 76 can be recorded along with the strength of the magnetic field at each of the positions. Then, corrective shimming, which can include a variety of ferromagnetic or non-magnetic materials in shapes and sizes as needed to minimize inhomogeneties in the filed B₀, for example, the steel balls 110, 112, soft iron plates (not shown), and others can be placed empirically (e.g., trial and error), or with the aid of a magnetic field computation program, as mentioned above. For example, with the map of the magnetic field B₀ obtained with the Hall magnetometer, including the inhomogeneities, a magnetic field computation program or method know to persons skilled in the art can be used to choose suitable corrective shimming to minimize the inhomogeneities in the field B₀. Then, with shimming in place as chosen with the aid of the computation program, the magnetic field B₀ can be mapped again with the Hall magnetometer to see if the corrective shimming was sufficient, or the coil 60 can be mounted and operated to obtain an NMR signal. If necessary, the shims can be adjusted empirically to improve the uniformity of the measured field B₀ or to enhance the NMR signal. When the Hall magnetometer measurements and/or the NMR signal indicate that the Field B₀ is adequately uniform with the shim or shims in particular locations and/or a good NMR signal is obtained, the shims can be left or fixed in those locations. In the example shown in FIGS. 3, 4, and 6, the steel ball shims 110, 112 are fixed in place on the external surfaces 79, 81 of the magnet disks 74, 76 by a suitable adhesive 111, 113.

Referring now primarily to FIG. 6, the size of the sample tube 40, including an enlarged section 58, if used, and the length of the pre-magnetizer magnet assembly 44 can be coordinated to provide enough dwell time of the fluid at a desired maximum flow rate to pre-magnetize the fluid enough so that the combination of the pre-magnetizer field Bₚ and the analytical magnetic field B₀ cause enough of the nuclear magnetic moments to approach equilibrium to get a good free induction decay (FID) and resulting NMR signal after application of the RF pulse, as explained above. Full magnetization, i.e., all of the hydrogen nuclear magnetic moments relaxed to equilibrium in the direction of the magnetic field B₀ as described above, is physically not possible to attain, but, in general, a dwell time in the magnetic field of about three times the relaxation time T₁ will usually achieve close to full magnetization of the fluid, for example, about 90 to 99 percent magnetization. However, the benefit of obtaining such almost full magnetization may not be worth the extra bulk, complexity, and cost of providing a large enough pre-magnetizer magnet assembly 44 and sample tube 40 combination to provide a dwell time of the fluid in the pre-magnetizer magnetic field Bₚ and analytical magnetic field B₀ equal to three times the relaxation time T₁. Something less may be sufficient. For example, it has been observed that a dwell time of about one T₁ in the pre-magnetizer magnetic field Bₚ usually provides enough magnetization (in the neighborhood of 60 to 80 percent) to obtain good NMR signals. Therefore, sizing the pre-magnetizer magnet assembly 44 and sample tube 40 to provide a dwell time of about 0.5 T₁ to 1.5 T₁ at the highest desired flow rate is a good design criteria or target for many applications.

For use of the NMR apparatus 10 as a flow meter, a coil depletion method has been developed to take advantage of the single coil 60 and combination pre-magnetization and analytical magnet design described above to produce fast, accurate, and reliable flow measurements, although the relaxation method mentioned above can also be implemented with the NMR flow meter apparatus 10 described above. In this coil depletion method, the fluid flows through the sample tube 40 in the pre-magnetizer field Bₚ in the pre-magnetizer zone 42 created by the pre-magnetizer magnet assembly 44 to become at least partially magnetized before entering the analytical field B₀ created by the analytical magnet assembly 48. The dwell time Tₚ spent in the pre-magnetizer zone 42 can be estimated as

Tₚ=Vₚ/Q

where Vₚ is the volume of the fluid in the sample tube portion that is in the pre-magnetizer zone 42 and Q is the volume flow rate. For adequate pre-magnetization, the time Tₚ should be greater than or at least comparable to the relaxation time T₁, for example, in a range of about 0.5 T₁ to 1.5 T₁, as indicated above for many applications. However, if the signal-to-noise ratio of the NMR signal is low, it may be necessary to use a dwell time Tₚ of as much as 3 T₁, whereas an application with a high signal-to-noise ratio may allow the dwell time Tₚ to be as low as 0.1 T₁. Therefore, the in balancing the available signal-to-noise ratio against size and weight of the apparatus needed, the dwell time Tₚ may be anywhere in a range of 0.1 T₁ to 3 T₁, and in many applications 0.5 T₁<Tₚ<1.5 T₁ will be satisfactory.

As mentioned above, the pre-magnetizer magnetic field Bₚ need not be as highly uniform as the analytical field B₀, and it is easier to maintain high magnetic field intensity all along the fluid flow path from the pre-magnetizer zone 42 into the analytical zone 46 if the pre-magnetizer field Bₚ is be oriented in the same direction as the analytical field B₀. The pre-magnetizing field Bₚ can be, but does not have to be, larger in magnitude than the analytical field B₀, or it can be weaker. However, in general, stronger magnetization of the fluid will result in better signal strength at the coil 60, so a strong pre-magnetizer field Bₚ has benefits.

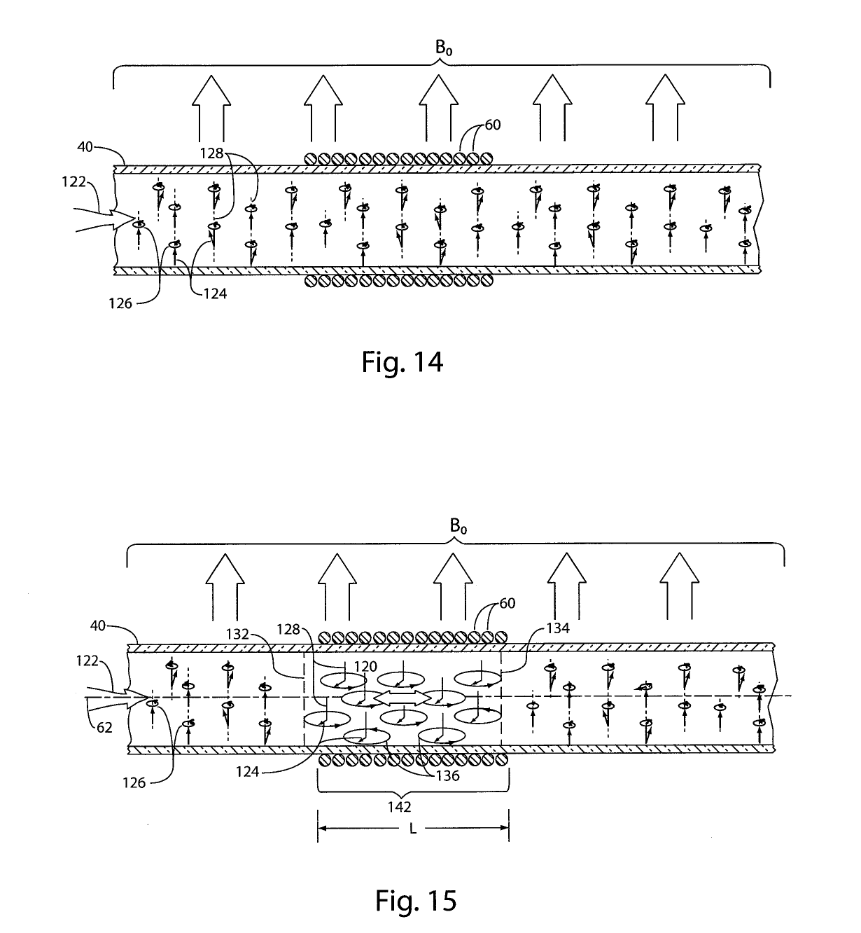

Essentially, as indicated diagrammatically for an idealized case in FIGS. 14-17, the magnetized fluid 120 flowing through the sample tube 40, as indicated by the flow arrow 122 in FIG. 14, has its nuclear magnetic moments 124 relaxed in an equilibrium state in which they are generally oriented in the direction of the very highly uniform analytical magnetic field B₀. In that equilibrium state, the nuclear magnetic moments 124 precess, as indicated by circular arrows 126, about axes 128 oriented in the direction of the uniform magnetic field B₀. As explained above, in a uniform field B₀, the hydrogen nuclear magnetic moments 124 of a particular atomic species all precess at the same rate, i.e., the Larmor frequency, or nearly so, but in random phases, as illustrated in FIG. 14. The amount of polarization illustrated in FIG. 14 is somewhat exaggerated for clarity and to facilitate this description. As also mentioned above, hydrogen has a large nuclear magnetic moment and is present in high number densities in nearly all fluids, so NMR measurements and analytics are typically performed utilizing the hydrogen nuclei, although other atomic nuclei with odd numbers of protons can also be used. Therefore, while this description may refer to hydrogen nuclei or hydrogen nuclear magnetic moments from time to time, such references are only for examples and not intended to limit the invention to hydrogen.

To measure the flow rate of the fluid 120 through the sample tube 40 with this coil depletion method, nuclear magnetic resonance (NMR) can be used to determine the mean velocity ν at which the fluid is flowing through the tube 40, and then, knowing the geometry and dimensions of the tube, the flow rate can be calculated from the relationship

ν=Q/A

where Q is the volume flow rate and A is the cross-sectional flow area of the sample tube 40 at the coil 60. However, as explained below, flow rate Q can also be determined with this coil depletion method directly from the ratio R of the amplitude of a second FID to the amplitude of a first FID, where the second FID results from a second excitation pulse applied after a chosen time delay τ between the first excitation pulse and the second excitation pulse. This method is distinct from the time-of-flight method mentioned above in which a magnetic tag is induced in the fluid and used to determine the time that it takes for the fluid to flow a set distance between two coils.

To determine the mean flow velocity ν, an RF pulse at the Larmor frequency is applied to the coil 60, which creates an alternating magnetic field B₁ in a direction at least a component of which is transverse to the magnetic field B₀ that simultaneously imposes coherency (same phase) on the precessing hydrogen nuclear magnetic moments 124 as it also rotates them to a plane that is orthogonal to the precession axes 128, as illustrated in FIG. 15. To maximize the signal to noise ratio of the resulting NMR signal, it is desirable for the direction of the alternating magnetic field to be oriented as much as possible in a direction transverse to the magnetic field B₀. Consequently, in the volume of fluid 120 that is influenced by the RF magnetic field B₁ from the coil 60 in the idealized illustrations, all of the hydrogen nuclear magnetic moments 124 are precessing at the Larmor frequency about the precession axes 128 in phase with each other. In the idealized illustrations of FIGS. 15-19, the volume of fluid that is influenced by the RF magnetic field B₁ is depicted as the volume of the flow channel (e.g., a portion of the tube 40) between the boundary lines 132, 134 that roughly correspond to the opposite ends of the coil 60, thus is sometimes referred to in this description as the coil volume 142. This idealized coherent precession in the coil volume 142 is indicated diagrammatically in FIG. 15 by all of the nuclear magnetic moments 124 in the coil volume 142 between the boundary lines 132, 134 pointing in the same direction as they precess about the axes 128 as indicated by circular arrows 136. The coherent precession (i.e., at the same frequency and phase) of all the hydrogen nuclear magnetic moments 124 in the coil volume 142 between the boundary lines 132, 134 results in all of the individual magnetic fields of each of the nuclear magnetic moments 124 adding together, and together they create a large enough composite magnetic field rotating at the Larmor frequency to be detected by the coil 60. The duration of the RF pulse required to rotate the nuclear magnetic moments 124 from the equilibrium state down to that 90° precession plane 136 illustrated in the coil volume 142 in FIG. 15 is sometimes called a 90° RF pulse or a 90° pulse.

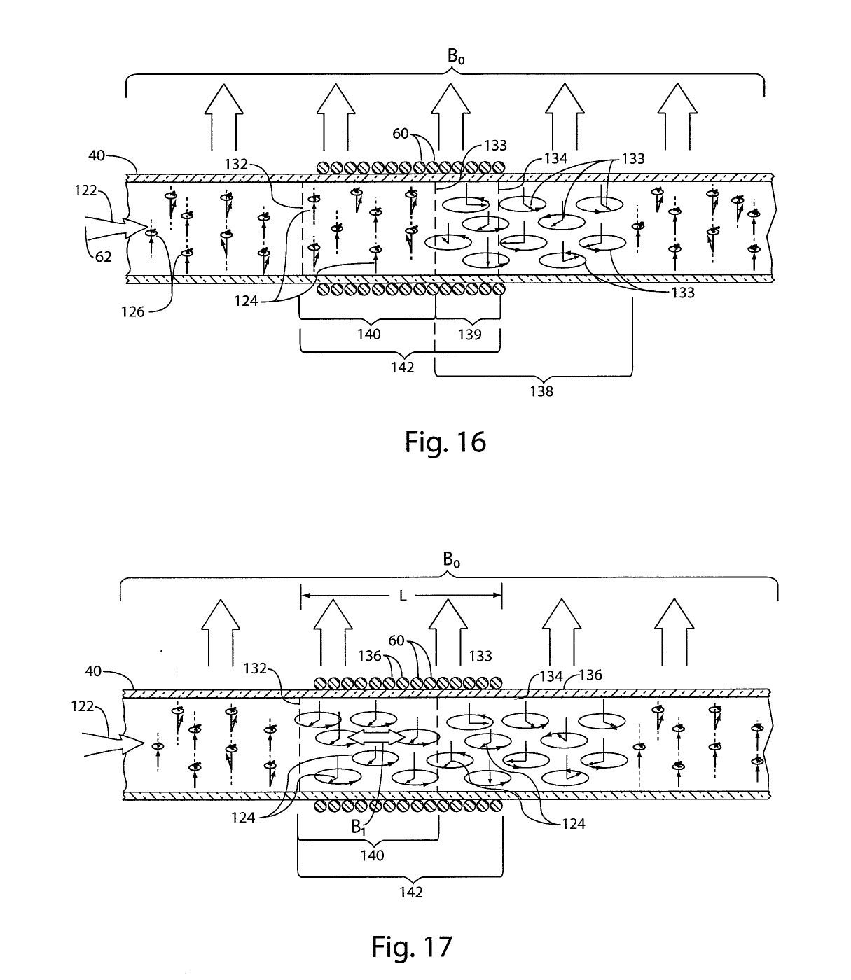

Referring again to FIG. 15, which illustrates the idealized result of a 90° RF pulse in the coil volume 142, as soon as the 90° RF pulse in the coil 60 is terminated, the signal induced by the precessing nuclear magnetic moments 124 in the coil volume 142 can be detected by the coil 60, and the signal detected is sometimes called the FID, FID signal, or the NMR signal. If no other processes or influences were at play, the NMR signal would decay slowly over the relaxation time T₁ starting when the 90° RF pulse in the coil 60 is turned off and continuing until the static equilibrium is re-established, i.e., when the precessing nuclear magnetic moments 124 in the coil volume 142 have relaxed back to the equilibrium state illustrated in FIG. 14 before the RF pulse was applied. However, long before such slow decay over the relaxation time T₁ can occur, other influences cause the precessing nuclear magnetic moments 124 to de-phase while they are still in the orthogonal(90°) precession plane 136, which results in the idealized state illustrated in FIG. 16, where all of the nuclear magnetic moments 124 are shown diagrammatically as still rotating in the orthogonal plane 136, but in random orientations that illustrate they are de-phased, i.e., randomly out of phase with each other.

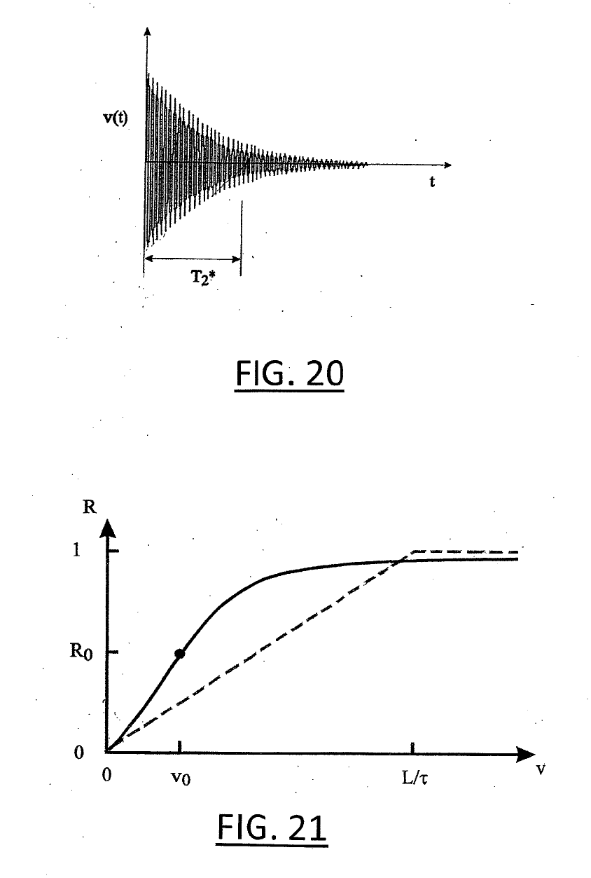

When the nuclear magnetic moments 124 are no longer in phase, as illustrated diagrammatically in FIG. 16, their individual magnetic fields begin to cancel each other out, and when they are totally out of phase, i.e., all of them are spread into random phases, they no longer produce any detectable NMR signal in the coil 60. This de-phasing causes the decay of the NMR signal, i.e., free induction decay (FID). The characteristic time that it takes for the NMR signal to decay due to the de-phasing effects is known as the transverse or spin-spin relaxation time T₂. A typical NMR signal is shown, for example, in FIG. 20, where ν(t) is the voltage induced in the coil 60, which is indicative of the FID, and t is time starting immediately when the RF pulse is terminated.

As mentioned above, there are many de-phasing influences in a physical system, one of which is slight inhomogeneities in the analytical field B₀, which are impossible to eliminate completely. Such inhomogeneities or non-uniformities in the field B₀ cause slight variations in the Larmor frequency (precession rate) in different regions of the sample. Those different precession rates cause different local magnetic field vectors that work against each other and over time contribute to the de-phasing of the nuclear magnetic moments. Such de-phasing induced by inhomogeneous field effects is sometimes denoted T₂*, and an example is shown on FIG. 20. The value of T₂ can be seen in FIG. 20, where a tangent of the envelope curve of the NMR signal at the starting point intersects the neutral axis. In the applications discussed herein, the predominant de-phasing mechanism that contributes to the observed decay is field inhomogeneity, so, for purposes of this description T₂ and T₂* are considered to be practically synonymous and may be used interchangeably. In other words, for the purpose of this application, T₂ is the general notation for de-phasing by any process, and it is dominated by T₂*.

In any event, the maximum amplitude NMR signal occurs immediately after the RF pulse is terminated and the nuclear magnetic moments 124 are still precessing in phase, as illustrated in FIG. 15, where each of the coherently precessing nuclear magnetic moments in the coil volume 142 contributes to the amplitude of the NMR signal. That NMR signal, when the coil volume 142 is still full of precessing nuclear magnetic moments, is detected, measured, and used in the determination of mean flow velocity ν and/or flow rate Q of the fluid 120 flowing through the sample tube 60, as will be explained in more detail below.

Referring now to the idealized illustration in FIG. 16, as time passes and the fluid 120 continues to flow in the tube 40, the de-phased or “depleted” volume or plug 138 of fluid (the initial equilibrium magnetization of the nuclear magnetic moments 124 still suppressed to the 90° plane 136, but out of phase and no longer capable of emitting a NMR signal) moves partially out of the coil volume 142 and is replaced by a fresh volume 140 with a supply of nuclear magnetic moments 124 that are still magnetized to the equilibrium state as induced by the uniform analytical magnetic field B₀. In FIG. 16, an idealized intermediate boundary line 133 is shown to help visualize a quantifying demarcation between the volume 139 of depleted fluid 138 that is still in the coil volume 142 and the volume 140 of freshly magnetized replacement fluid that has moved into the coil volume 142. In reality, there is not such a clear, distinct line of demarcation, but this idealized visualization helps in the explanation. This coil volume 142, which is still partially filled with a volume 139 of dephased or depleted fluid with depressed magnetization that cannot produce a NMR signal, and which is partially filled with a volume 140 of freshly magnetized fluid, provides the setting for a second NMR signal that, with the first NMR signal described above, forms the basis for a measurement of the mean velocity ν and/or flow rate Q of the flowing fluid.

Referring now to FIG. 17, after a time delay τ from the start of the first 90° RFpulse described above, which produced the NMR signal from the coherently precessing nuclear magnetic moments 124 in the entire coil volume 142 (FIG. 15), a second 90° RF pulse at the Larmor frequency is applied by the RF coil 60 to the fluid in the coil volume 142 to produce the idealized result illustrated diagrammatically in FIG. 17. Essentially, because the hydrogen nuclear magnetic moments 124 in the new volume 140 of fresh fluid were still magnetized, the second 90° RF pulse has the same effect on them as described above, i.e., imposes a single phase on all of them at the Larmor frequency as it drives them to rotate down 90° to precess coherently in the 90° plane 136. Therefore, as soon as the second 90° RF pulse is terminated, those coherently precessing nuclear magnetic moments 124 in the partial volume 140 produce a second NMR signal as they go through the free induction decay (FID) in the same manner as described above. The highest amplitude of this second NMR signal occurs as soon as the second 90° RF pulse is terminated, for the reasons described above, and it decays in a spin-spin relaxation time T₂, as also explained above.

However, the previously depleted portion of the fluid in the coil volume 142, represented diagrammatically by the volume 139 between the intermediate line of demarcation 133 and the downstream coil boundary line 134, does not produce or contribute significantly to the second NMR signal. The second 90° RF pulse applied to the nuclear magnetic moments 124, which are in random phase distribution and not recovered to any significant degree from the 90° plane 136 back toward equilibrium, does not result in any significant FID or NMR signal. In order for the RF magnetic field B₁ in the direction that is orthogonal to the direction of the analytical field B₀ to excite or interact with the nuclear magnetic moments 124 in a manner that imposes phase on them, there has to be a vector component of the nuclear magnetic moments 124 that is parallel to, i.e., aligned with, the analytical field B₀. That condition does not exist for the nuclear magnetic moments 124 that are precessing randomly in the 90° planes 136, so they are substantially immune to the second 90° RF pulse for purposes of producing or contributing to the second NMR signal, at least not in the idealized case where it is presumed that no re-magnetization occurs in the time delay τ between the first and second pulses.

Therefore, the amplitude of the second NMR signal from the coil volume 142 after the second 90° RF pulse is proportionately less than the amplitude of the first NMR signal, because there are proportionately fewer coherently precessing nuclear magnetic moments 124 in the coil volume 142 contributing to the second NMR signal as compared to the number of nuclear magnetic moments 124 in the coil volume 142 that contributed to the first NMR signal, when the coil volume 142 was full of coherently precessing nuclear magnetic moments. Therefore, the amplitude of the second NMR signal after the second pulse is proportional to the fraction 140 of the coil volume 142 that has been refilled during the delay time τ between the first 90° RF pulse and the second 90° RF pulse. Consequently, knowing the geometry of the sample tube 60 at the coil volume 142 (e.g., the inside diameter d of the tube) and the length L of the coil 60, the full coil volume 142 between the boundary lines 32-34 can be calculated (e.g., coil volume V=L·πd²/4). Then, multiplying the coil volume V by the ratio R of the second NMR signal amplitude to the first NMR signal amplitude gives the volume V (i.e., the partial volume 140) of fluid that flowed into the coil volume 142 in the time delay τ between the first 90° RF pulse and the second 90° RF pulse. Therefore, the flow rate Q is the volume of the fluid 139 that flowed into the coil volume 142 divided by the delay time τ.

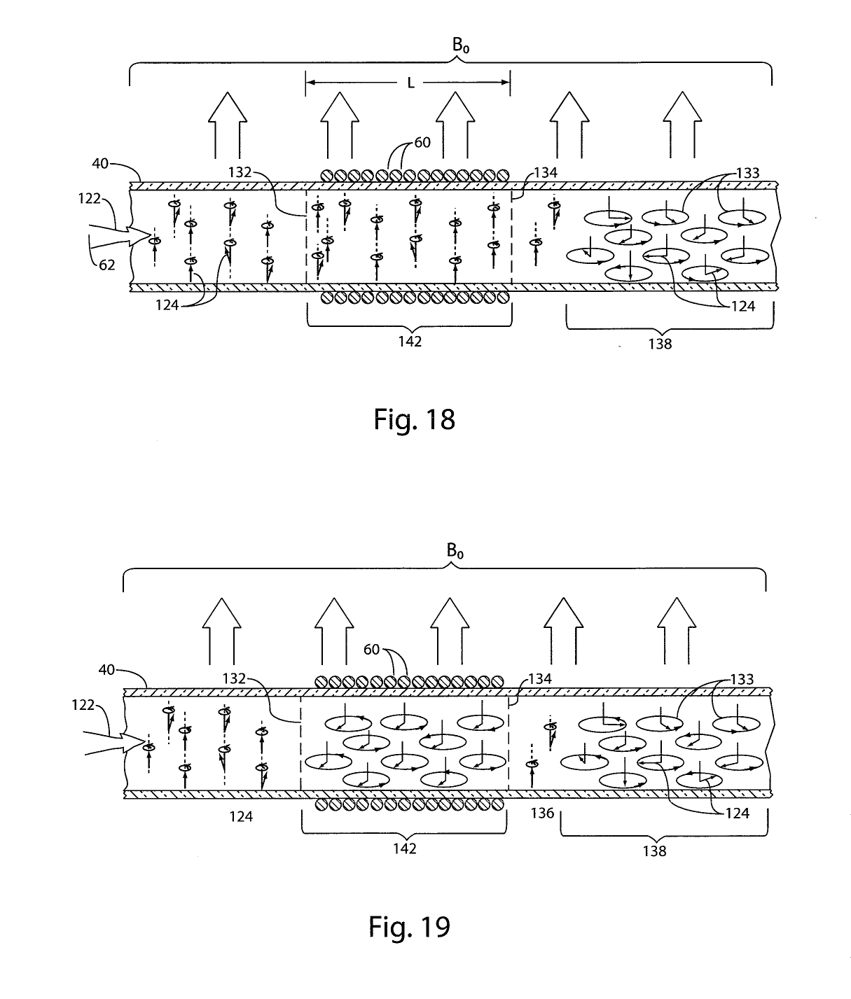

For this coil depletion method of determining flow rate, the time delay τ between the first and second 90° RF pulses has to be short enough that all of the depleted fluid 138 does not flow completely out of the coil volume 142 before the second 90° RF pulse is applied. If that condition of the depleted fluid flowing completely out of the coil volume 142 should occur, the entire coil volume 142 would be re-filled with fresh, magnetized nuclear magnetic moments, as shown in FIG. 18, and, upon application of the second 90° RF pulse, the entire coil volume 142 would have new, coherently precessing nuclear magnetic moments 124 contributing to the NMR signal, as illustrated in FIG. 19, the same as the first NMR signal, as illustrated in FIG. 15. Therefore, the resulting amplitude of the second NMR signal would be the same as the amplitude of the first NMR signal, and the ratio R of the second NMR signal amplitude to the first NMR signal amplitude would be one, regardless of the delay time τ between the first and second RF pulses. In other words, for any delay time τ that is large enough for all of the depleted fluid 138 to have moved out of the coil volume 142, the ratio R is insensitive to flow rate Q. However, for time delays τ less than the time it takes for all of the depleted fluid to flow out of the coil volume 142, the ratio R of the second NMR signal amplitude to the first NMR signal amplitude is a good indicator of volume flow rate Q of the fluid. Therefore, a time delay τ between the first and second pulses has to be chosen to be short enough so that less than all of the depleted fluid from the first pulse has flowed out of the coil volume 142 when the second pulse is applied.

Therefore, in general, the basic pulse sequence for measuring flow with this coil depletion method is 90°-τ-90° with NMR signals recorded immediately after each 90° pulse. Before the first 90° pulse, the fluid is magnetized throughout the coil volume 142. The first pulse suppresses the magnetization within the coil volume 142 and generates a FID or NMR signal that has maximum amplitude and can be detected with the coil 60. The delay time τ between the first and second pulses is chosen so that the depleted coil, i.e., coil volume 142 with suppressed magnetization, will be partially refilled with magnetized fluid at the time of the second pulse. The FID amplitude after the second pulse is proportional to the fraction of the coil volume that has been refilled with magnetized fluid and is a measure of the flow rate. The 90° pulse time and the FID duration are both much less than τ, so the fluid is nearly or practically stationary on these time scales.

This coil depletion method of flow measurement can be made nearly insensitive to the spin-lattice relaxation time T₁ by using the ratio R of the second pulse amplitude to the first pulse amplitude of the flow-measuring parameter. When using this parameter, i.e., a ratiometric type of measurement, the inferred flow velocity does not depend strongly on the degree of pre-magnetization, because the pre-magnetization is substantially the same for both the first and the second signal, and any effect the degree of pre-magnetization has on the amplitude of the FID signals is the same in both the numerator and denominator of the ratio. Therefore, as discussed above, it is feasible for many applications to allow the dwell time that the fluid is in the pre-magnetizer zone 42 (FIG. 6) to be approximately on the order of the relaxation time T₁ or within the ranges described above without it being necessary for the dwell time to be very much, if any, more than the relaxation time T₁ or within the ranges described above. This freedom to keep the dwell time in the pre-magnetizer down to the neighborhood of T₁ or within the ranges described above for many applications greatly reduces the required pre-magnetizing volume (volume of fluid in the pre-magnetizer zone 42) as compared to other NMR measurement methods, where specific individual values, as opposed to ratios, are the measuring parameters. There could still be a small dependence on T₁ due to re-magnetization of the depleted fluid in the coil volume 142 during the time delay τ between the first and second pulses due to the presence of the analytical magnetic field B₀. However, this effect is minimal in this coil depletion method and much less important than in the other NMR flow measurement methods discussed above, because the distance the fluid travels in the delay time τ between critical events (e.g., the first and second pulses) in the measuring technique is so much shorter (e.g., a fraction of the coil length L). Therefore, the delay time τ between the first and second RF pulses, in which re-magnetization could be a factor, is also shorter than time periods in other methods that are vulnerable to re-magnetization, and the delay time τ is very much shorter than the relaxation time T₁.

For example, referring again to the idealized flow illustrated in FIGS. 14-17 (e.g., well-defined coil volume 142 corresponding to an idealized assumption that the RF magnetic field begins and ends abruptly at the boundary lines 132, 134 corresponding to the opposite ends of the coil 60 and the idealized assumption that the fluid flows in well-defined, cylindrical “plugs” of fluid in which the flow profile, i.e., flow velocity throughout the cross-section of the fluid, is uniform), the ratio R can be expressed as:

$$R = \frac{{A}_{2}}{{A}_{1 }} = 1 - ( 1 - \frac{v τ}{L} ) {e}^{- \frac{τ}{{T}_{1}}}$$

where A₁ is the FID amplitude after the first excitation pulse, A₂ is the FID amplitude after the second excitation pulse, ν is the average flow velocity, τ is the delay time between the first and second pulses, L is the length of the coil 60, and T₁ is the spin-lattice relaxation time in the analytical field B₀. Therefore, this relationship does take into account any re-magnetization of the fluid during the delay time τ due to the analytical magnetic field B₀. However, where τ is very much smaller than T₁ (e.g., τ<<T₁), so that τ/T₁ effectively goes to zero and the exponential goes to 1 in the above relationship, thus virtually no re-magnetization, then the ratio R is:

$$R = 1 - ( 1 - \frac{v τ}{L} ) ( 1 ) = \frac{v τ}{L}$$

where the resulting numerator and denominator represent the fraction of the coil length L that the fluid flows in the delay time τ. Therefore, the ratio R of the amplitude A₂ of the second NMR signal to the amplitude A₂ of the first NMR signal is proportional to average flow velocity ν of an idealized fluid when the delay time τ between the two pulses is very much smaller than the spin-lattice relaxation time T₁. Otherwise, for a longer delay time τ, re-magnetization would begin to have an effect on the ratio R and could lead to inaccuracies in flow rate measurement. Consequently, it is desirable for the delay time τ between the pulses to be small so that re-magnetization of the depleted fluid is not a significant issue, while, of course, keeping τ long enough to allow enough partial refilling of the coil volume 142 with enough fresh magnetized fluid to get a good, useable, NMR signal. Of course, where the tube 40 has a constant diameter d and cross-sectional area A, the ratio R is also proportional to flow rate Q, as will be explained below.

The ratiometric technique used to measure flow velocity ν and/or rate Q in this method, i.e., utilizing the ratio R of the second FID amplitude A₂ to the first FID amplitude A₁ as the flow measuring parameter, makes the measurements relatively immune to variations of proton density in the fluid and to variations in electronic circuit characteristics. For example, if the gain of the amplifier changes or drifts due to temperature or other factors, then the apparent amplitude of both the first and second NMR signals, i.e., both the numerator and denominator in the ratio R, change by the same factor and cancel each other out.

The dependence of the NMR signal amplitude ratio R on flow velocity ν is shown in FIG. 21, where the broken line curve represents an idealized NMR system illustrated in FIGS. 14-19, and the solid line curve represents behavior actually observed. The simplest, idealized representation, i.e., the broken line curve in FIG. 21, is based on the supposition that the flow velocity ν is uniform in the coil region, e.g., that the fluid 120 actually moves through the sample tube 60 in discrete “plugs”, such as the discrete volume 138 of depleted fluid illustrated diagrammatically in FIGS. 16-19, and that the RF field B₁ is uniform within the coil volume 142 and drops off abruptly at the end boundaries 132, 134 and that τ<<T₁, i.e., no significant re-magnetization, so that the RF field B₁ does not extend beyond the length of the coil 60. In such an idealized system, as shown by the inclined portion of the broken line curve in FIG. 21, the ratio R between the second NMR signal amplitude and the first NMR signal amplitude will simply increase linearly with flow velocity ν in direct proportion to the fraction 140 of the coil volume 142 refilled by magnetized fluid at the time of the second 90° RF pulse (see FIG. 17). If the flow velocity ν gets large enough so that the coil volume 142 is completely refilled with fresh magnetized fluid before the delay time τ, as illustrated in FIGS. 18 and 19, the ratio R of the second NMR signal amplitude to the first NMR signal amplitude will be equal to one (1) and will be independent of flow velocity as illustrated by the flat, horizontal portion of the broken line curve in FIG. 21.

The dimensionless sensitivity can be defined as

$$\sum = \frac{\partial R}{\partial v} \frac{v}{R} .$$

With this definition, a fractional change of amplitude ratio ΔR/R is related to a fractional change of flow velocity by Δν/ν by

$$\frac{Δ R}{R} = \sum \frac{Δ v}{v} .$$

For the idealized case represented by the broken line curve in FIG. 21, the sensitivity E is equal to unity for ν<L/τ and zero for ν>L/τ.

The solid line curve in FIG. 21 is a close approximation to the ratio R as a function of flow velocity R(ν) dependence actually observed in a proof-of-concept apparatus. The flow velocity ν is interpreted as the mean velocity, defined as

ν=Q/A

where Q is the volume flow rate and A is the cross-sectional area of the flow channel, e.g., sample tube 40, at the coil 60. The sensitivity Σ now depends on the flow rate Q. It reaches a maximum value Σ₀≈1.2 at ν₀=0.2 L/τ and R≈0.5. The sensitivity drops by less than about 20% for flow velocity within the interval

ν₀/1.5<ν<ν₀·1.5.

High sensitivity is thus retained for flows varying by a factor of about 1.5²=2.25 (a turn-down of 2.25) for a single value of τ. Turn-down essentially means a range as expressed by the highest flow rate divided by the lowest flow rate, and for a single value of τ, the turn-down or range is not large. However, high sensitivity over a much larger region can be achieved by defining a series of overlapping flow rate ranges with different values of time delay τ, because, with this coil depletion method, the time delay τ can be varied or set to whatever value is needed to apply the second pulse before the coil volume 142 is cleared of depleted fluid, as explained above. Therefore, for higher flow rate ranges, the delay time τ can be set shorter, and for slower flow rate ranges, τ can be reset to longer times. Such switching between different values of τ for different flow rate ranges can be done manually or automatically by programming the controller to switch to a new τ when the measure flow rates approach predetermined upper and lower limits in each flow rate range. Therefore, with high sensitivity for a particular delay time τ extending over a turn-down of greater than 2.0, along with the ability to vary τ almost to whatever value is needed for high sensitivity at a particular flow rate range, the effective turn-down or range can be as high as 100 to 1, which is a large range for a flow meter.

In the explanation of the example implementations above, the RF pulse is described as a 90° pulse, and the NMR signal in the explanation above is based on the FID from a 90°pulse. Therefore, if an error is made in the duration of the pulse, i.e., a duration that causes more or less than 90° rotation of the magnetic field M₀ of the fluid, the coil volume 142 will not be fully depleted of fluid magnetization after the first pulse. Such incomplete depletion of fluid magnetization after the first pulse will influence the amplitude of the FID after the second pulse, and the indicated flow rate will be in error. Therefore, while there are other pulse durations and sequences that can be used to provide a NMR signal (for example, spin echo), when 90° pulses and FID are used to get an NMR signal, errors in the pulse duration should be minimized. Consequently, it may be desirable to take reasonable measures to ensure that the time duration of the pulse is correct for rotating the field of the nuclear magnetic moments to the plane that is 90°, i.e., orthogonal, in relation to the analytical magnetic field B₀. However, even when the time duration is set initially to a correct value for a 90° pulse, vagaries inherent in electronics and other systems due to temperature changes and other causes, for example, in power amplifier gain, matching network tuning, coil quality-factor and analytical field strength B₀, the pulse duration can drift. Ideally, if the fluid is stationary, i.e., flow is stopped, in the sample tube 40, the second FID, thus second NMR signal, would have zero amplitude (assuming the time delay t between pulses is short enough to avoid any significant remagnetization of the fluid in the coil volume 142), because, if the fluid was stationary, all of the depleted fluid in the coil volume 142 would remain in the coil volume 142 and not get replaced. The ratio R of the second NMR signal to the first NMR signal would then also be zero. Therefore, the fluid flow in the sample tube 40 can be stopped periodically in order to “zero” the pulse duration setting to a pulse time duration for the first and second pulses that results in zero amplitude for the second FID signal.

In reality, though, the drift or variations in actual pulse duration can occur continuously or frequently, and it may not be practical to actually stop the flow in order to run tests frequently enough to ensure that the pulse durations are always set properly to produce 90° rotation of the fluid magnetization M₀ with respect to the analytical field B₀. However, the apparatus and coil depletion method described above can accommodate a technique for automatically “zeroing” the pulse duration setting while the fluid is flowing. To do so, the delay time τ between the first and second pulses can simply be adjusted to a very short time, so that, in ordinary flow rates, the fluid in the coil volume 142 will have hardly moved at all, e.g., an insignificant amount, during that interval between the first and second pulses. Insignificant here means that there would be not enough difference between the actual amount of flow during the time interval and no flow to be of concern in practical applications of this method or in use of the apparatus in practical applications. Therefore, the effect is as if the flow was virtually stopped during the two pulses and the resulting first and second FID signals. It is somewhat analogous to using a fast shutter speed on a camera to snap a photograph of a moving object, and the captured picture makes the object appear to have been stopped just for an instant. A delay time τ in a range of 0.1 to 2.0 milliseconds (ms) can usually be used for this purpose, depending on the characteristics and flow rates of the fluid being measured. The amplitude of the second FID signal, i.e., the NMR signal resulting from the second pulse, should be zero or as close to zero as possible. If it is not zero, the pulse duration can be changed and retried iteratively and/or by calculation or extrapolation until the ratio R converges to zero or as close to zero as practical. Persons skilled in the art know how to make pulse duration time adjustments and to make converging calculations and implementations by software, so further details of implementation are not needed for an understanding of this feature. Once the pulse duration has been zeroed, the delay time τ can then be re-set to its usual time, typically about 5 ms to 200 ms. In cases where the re-magnetization errors are too large to be ignored (for example, at low flow rates where the normal delay time τ between the first and second pulses has to be longer in order to allow enough fresh, magnetized fluid 120 to displace FID depleted fluid in the coil volume 142 to enable acquisition of a useful ratio R value), such errors can be corrected with a correction factor based on an approximate knowledge of the relaxation time T₁. If necessary, T₁ can be measured under stopped flow conditions.

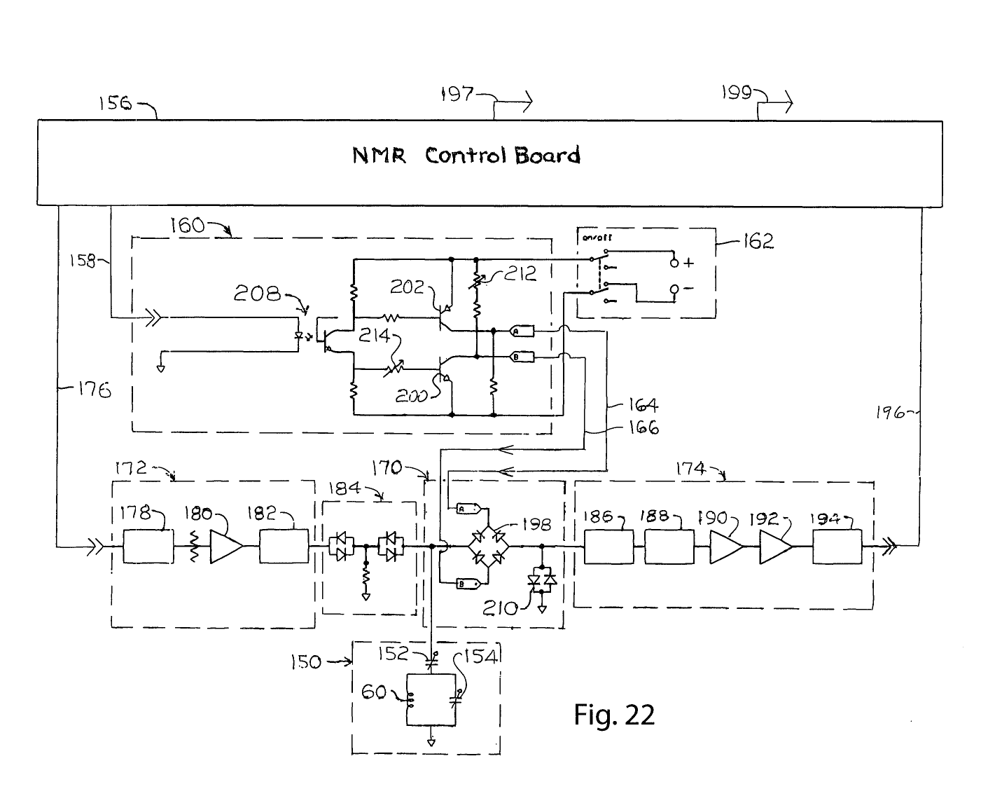

Persons skilled in the art are generally capable of designing and making electronic circuits for creating RF pulses, driving RF coils, and receiving and processing NMR signals from coils in response to FID, and electronics packages and circuit boards for NMR applications are available commercially from a number of manufacturers and vendors, including, but not limited to, SpinCore Technologies, Inc., of Gainesville, Fla. For example, the RadioProcessor™ printed circuit board is advertised by its manufacturer, SpinCore Technologies, Inc., as a complete system console for nuclear magnetic resonance, including excitation and acquisition components, that generates completely formed RF excitation pulses and control signals and captures and digitally demodulates RF signals, as definable through software, and autonomously signal-averages the baseband data between multiple acquisitions, as well as numerous other controls and functions for NMR systems that are useful for operating the NMR apparatus and implementing the methods described herein. An example filter and switch circuit that utilizes such commercially packaged NMR electronics for driving the coil and receiving and processing signals is shown in the schematic diagram in FIG. 22, although many other circuits could be used instead.

In FIG. 22, the RF coil 60 is part of the probe circuit 150 that includes two matching capacitors 152, 154 for tuning the resonant LC circuit to an appropriate impedance at the NMR signal frequency. As explained above, the RF coil 60 is used both to apply the RF excitation pulse to the fluid and to receive the resulting FID signal from the excited fluid. The NMR control board 156 can be any of a number of commercially available NMR control electronics packages or products, for example, a RadioProcessor™ made by SpinCore Technologies, Inc., of Gainesville, Fla., which synthesizes and times RF pulses and includes a receiver with a quadrature mixer, filtering, decimation, and data memory, or, if desired, smaller, more stripped down or dedicated versions can be made by persons skilled in the art with only the functionalities desired for a particular application or packaged device. Pulse and data acquisition sequences can be programmed by persons skilled in the art over a USB or other port to a computer (not shown) or any microprocessor circuit, for example, in a packaged device, such as the example flow meter 10 illustrated in FIG. 1 with dedicated electronics 22, display and control panel 26 for direct display for fluid flow rate, application specific menu and input/output, and the like, all of which can be done by persons skilled in the art. After a pulse program is run, the USB link or other communication link can be used to transfer data from the NMR control board 156 to the computer or processor (not shown in FIG. 22, but which may be part of the electronics 22 in FIG. 1 and/or external components, as desired).

Outputs controlled by the pulse program can be output by the NMR control board 156 via a cable 158 or other communication or data link to a transmit/receive switch driver circuit 160. The NMR control board 156 and its functions are controllable by software according to documentations and instructions provided by the manufacturer or by the customization for particular applications, as is within the capabilities of persons skilled in the art. The switch driver circuit 160, which can be powered by any convenient power supply 162, responds to signals from the NMR control board 156 via the link 158 to output a voltage bias on either the output A or the output B via leads 164, 166, respectively, to the transmit/receive switch circuit 170. The transmit/receive switch 170 is actuated by the voltage biases from the switch driver circuit 160 to either direct a RF excitation signal from the transmitter circuit 172 to the coil 60 or to direct the FID signal from the coil 60 to the receiver circuit 174.

The transmitter circuit 172 receives a pulsed oscillatory signal from the NMR control board 156 at a frequency that is either set into, or determined by, the NMR control board 156, generally at or near the Larmor frequency (e.g., in a range of about 10 to 30 megahertz (MHz)), via a lead 176. The signal on the lead 176 from the NMR control board 156 is smoothed by a low pass filter 178 and then drives a power amplifier 180. The power amplifier 180 is followed by another low pass filter 182 to smooth the amplified signal and through a PIN diode isolator 184, which passes the RF signal from the transmitter circuit 172 to the coil 60. However, the PIN diode isolator 184 presents a high impedance to the probe circuit 150 when the transmitter 172 is turned off or not transmitting. Also, when the transmitter 172 is off, the PIN diode isolator 184 acts as a filter, attenuating noise from the transmitter during FID signal acquisition.

The receiver circuit 174 is basically a RF signal conditioning and pre-amplification circuit for the NMR signal acquired by the coil 60 from the FID of the excited fluid. It can comprise, for example, one or two low pass filters 186, 188 to smooth the signal, one or two pre-amplifiers 190, 192, and another low pass filter 194 to smooth the amplified signal. The pre-amplified and smoothed NMR signal is then sent via a lead 196 to the NMR control board 156 for further processing. An interface 197 can be provided for connection to the input/output board 26 (FIG. 1), as explained above, and a standard interface 199 can be provided, for example, a RS-485, suitable for reading out flow and/or analytical data to, or receiving input from, an external computer (not shown), as mentioned above.

The transmit/receive switch 170 comprises a diode bridge 198 for fast recovery to accommodate fast switching between the transmit mode, when the RF excitation pulse is transmitted to the coil 60, and the receive mode, when the NMR signal generated in the coil 60 by the FID is received by the receiver circuit 174 for pre-amplification and conditioning. The bridge diode switch 198 is controlled by the switch driver circuit 160 to be open, i.e., off, when a RF pulse signal is transmitted by the transmitter circuit 172 to the coil 60, thereby isolating the receiver circuit 174 so that the pre-amplifiers 190, 192 in the receiver circuit 174 do not get swamped or saturated by the transmitted RF pulse signal. The pre-amps 190, 192 are isolated from the transmit signal, because the high power of the transmit signal would saturate them, which would slow their recovery to a state wherein they could receive and amplify the NMR signal. The FID only lasts about 150 μs, so the switch from transmit mode to receive mode should occur very fast, and the receiver circuit 174 has to start operating very fast, for example, within about 20 μs, after the end of the RF pulse transmission in order to capture the best part of the FID signal before it decays. The diode bridge switch 198 allows for such fast switching and fast recovery. It closes, i.e., is turned on to allow signals to pass through it, by the switch driver circuit 160 as soon as the RF pulse transmission ends.

The switch driver circuit 160 responds to signals from the NMR control board 156, for example, a transistor transistor logic (TTL) signal, via the lead 158 to turn the bridge diode switch 198 on and off. Essentially, a low signal from the NMR control board 156 causes the transistors 200, 202 to be off, which allows switch output B to be positive and switch output A to be negative and thereby turning the diode bridge switch 198 on during acquisition of the NMR signal from the coil 60. A high signal from the NMR control board 156 on the lead 158 at all other times, including during RF pulse transmission, turns the transistors 200, 202 on to make the driver output A positive and driver output B negative to turn the bridge diode switch 198 off to isolate the receiver circuit 174. To avoid leakage of digital signals into the amplifiers 190, 192, the control signal from the NMR control board 156 is shown as being optically isolated by an optical coupling 208. The crossed diodes 210 to ground at the output of the diode bridge switch 198 are provided to protect the receiver circuit 174 from high power transmissions in the event a software error causes the diode bridge switch to stay on during transmission of a RF pulse to the coil 60. The trimmers 212, 214 in the switch driver circuit 160 are provided to reduce switching transient signals. As mentioned above, the NMR control board 156, if obtained from a vendor or manufacturer, such as SpinCore Technologies, Inc., usually comes with, or has available, documentation and software for programming, inputting parameters and commands, and operating all the functions associated with generating and receiving NMR signals, although other technical computing software, for example, MATLAB, available from The Mathwork, Inc., of Natick, Mass., and several open source alternatives, such as GNU Octave, FreeMat, and Scilab, can also be used. For example, control routines are available or can be set up in the software mentioned above for the desired pulse sequence and data acquisition parameters. Then a loop can be entered to repeatedly trigger the NMR control board 156, wait for data to be ready, and then collect and display data. For the example flow measurement process described above, each time the NMR control board 156 is triggered, it executes a sequence of two pulses, collecting FID data in separate memory areas after each pulse. The two-pulse sequence is repeated a number of times, called scans, and the time-domain data is averaged in the NMR control board 156. When the desired number of scans is completed, data is transferred to the computer or other processor and can be displayed, if desired, in time-domain and/or as a power spectrum. The process is then repeated a number of times, called runs. After the desired number of runs is completed, the average-over-runs of the FID amplitudes and of the ratios R of second FID amplitude to first pulse FID amplitude are calculated and can be displayed and/or stored for applications and other purposes. The standard deviations of those quantities can also be computed and stored or displayed. The data structure can be saved in memory, if desired. In a dedicated system or commercial product, such as the example flow meter/controller 10 in FIG. 1, the control routines, pulse generation parameters and sequencing, auto-zeroing, data collection, analysis, storage, averaging, display codes, outputs, and other processing can be done by an embedded or dedicated micro-controller in the NMR control board 156 or other on-board electronics 22 by persons skilled in the art.

In an optional variation, each 90 degree pulse can be replaced by a spin echo sequence, e.g., (90°-τ₁-180°-τ₁-echo)-τ-(90°-τ₁-180°-τ₁-echo) with τ₁ being a much shorter time than τ. For example, τ₁ may be about 1 millisecond. Data can be recorded during the FID that occurs right after the 90° pulses and during the spin echo. An advantage of using spin echoes for the NMR signal used in the ratio R is that the NMR signals can be recorded for a longer total time, which may yield better signal-to-noise ratio. The 90 degree pulses can also be replaced by multiple spin echo sequences, which are known to persons skilled in the art.

The amplitude of each NMR signal for use in determining the amplitude ratio R could be taken at a particular point in the NMR signal, e.g., near the start of the FID signal (see FIG. 20), where the amplitude is at or near its highest value, but a better approach for better signal-to-noise ratio and a more accurate result is to consider the total energy in each NMR signal rather than an amplitude at a single point in the signal. Therefore, a suitable filter that maximizes the signal-to-noise ratio can be used in the determination of NMR signal amplitude values for use in calculating the amplitude ratio R of second to first NMR signals. Suitable filters can be constructed in various ways by persons skilled in the art. In one example, each data point is weighted in proportion to its signal-to-noise ratio and then averaged with all other data points. While it is contemplated that more refined filters may be developed, in one filter that has been used for the coil depletion method described above, the algorithm first multiplies the data in time-domain by an exponential envelope that decays with a time constant approximately equal to the FID decay time T₂*. Next, the data are multiplied by a Bartlett-Hann window and fast Fourier transformed. The power spectrum is formed, and its peak is found. Then, the power in a selected number of bins around the peak is summed, and the square root is taken to form a measure of the FID amplitude.

### Example I

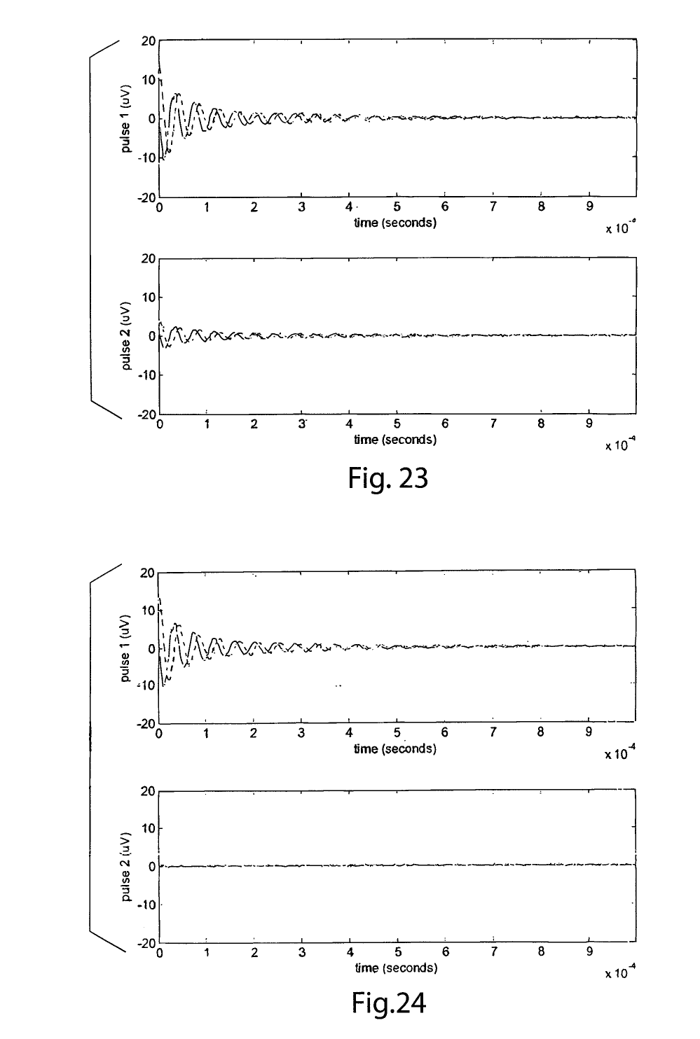

An example of FID signals for two successive 90° RF pulses is shown in FIG. 23. The flow rate is 40 ml/min, the time delay τ between the pulses is 30 ms, and the sequence repeat time between successive pairs of first and second 90° RF pulses is 0.25 seconds. Ten seconds of data are averaged. The 90° RF pulse duration is close to 10 μs, and the Larmor frequency is 17.996 MHz.

The upper panel in FIG. 23 shows the FID signal after the first 90° RF pulse, when the coil volume 142 (FIGS. 15-17) was filled with magnetized fluid (tap water in this example). The mean time for this fluid to transit the length L of the coil 60 at this flow rate is 150 milliseconds (ms), so, with this delay time τ of 30 ms, the fluid has moved about 0.2 of the length L of the coil 60 at the time of the second 90° RF pulse, based on the average flow velocity ν. As discussed above, this is the situation for maximum flow sensitivity. The second FID signal is shown in the lower panel of FIG. 23, and by visual inspection, the amplitude of the second FID signal appears smaller than the first FID signal, as expected under these conditions.

Except for the difference in amplitudes, the two FID signals in FIG. 23 have nearly identical waveforms, and they both have the same decay time of about 150 microseconds (μs). The solid and broken line curves correspond to real and imaginary parts, respectively, of the output of the digital quadrature mixer, which is used to down-convert the FID signal before it is stored in memory. The FID frequency is slightly offset from the RF oscillation, so the oscillation frequency in FIG. 23 corresponds to the difference between the FID frequency and the oscillation frequency.

### Example II

Two FID Signals under the same conditions as Example I, except that the delay time between the first and second 90° RF pulses is only one (1) ms, are shown in FIG. 24, and it illustrates the condition for auto-zeroing discussed above. This delay time τ is fast enough that the coil volume 142 (FIGS. 15-17) is still virtually completely depleted of magnetization from the first pulse and FID at the time of the second 90° RF pulse. Therefore, the amplitude of the second FID signal in the lower panel of FIG. 24 is very small—almost non-existent, as the amplitude ratio R of the second FID signal to the first FID signal (upper panel) is at or near zero. (Then if the ratio R is not zero, adjustment in this short time delay τ condition can be made in the RF 90° pulse duration to produce FID signals with amplitudes that yield a ratio R of zero, i.e., a second FID signal with zero amplitude, as explained above.)

### Example III

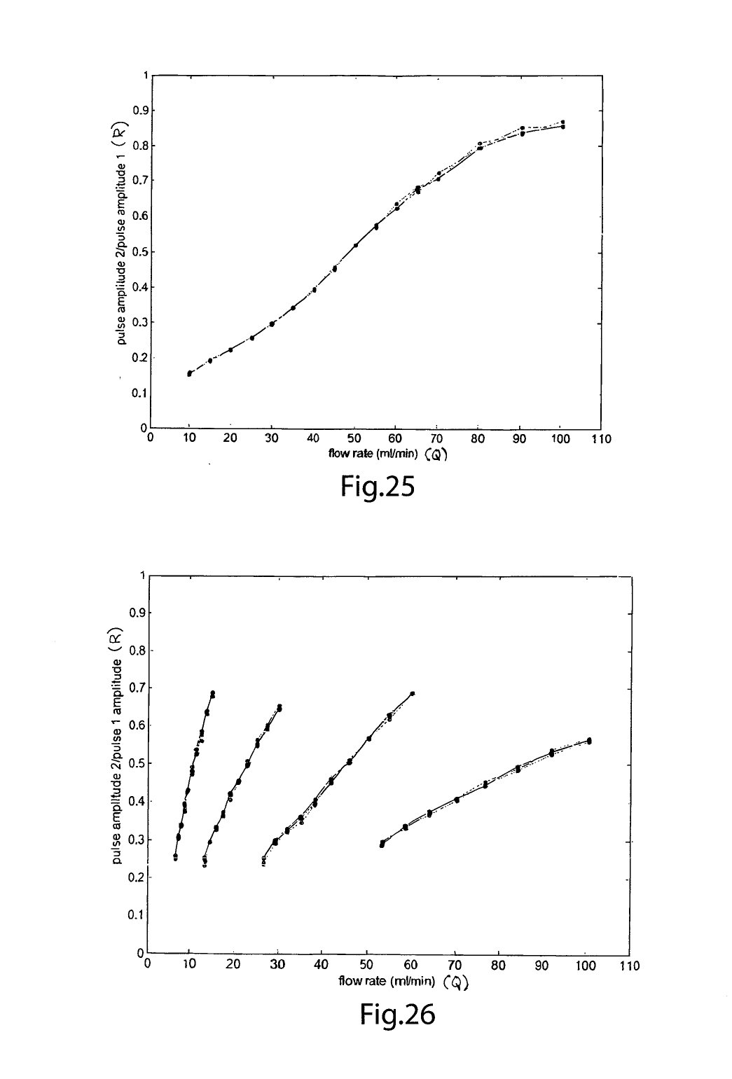

An example of dependence of FID signal amplitude ratio R on flow rate for a 25 ms time delay τ is shown in-between first and second 90° RF pulse pairs and a 0.2 second repeat time between successive 90° RF pulse pairs in FIG. 25. The 90° RF pulse duration is close to 10 μs and the Larmor frequency is 17.996 MHz. The actual flow rates were measured concurrently with a Coriolis flow meter. The three lines in the curve correspond to three separate data sets taken over a two hour period. They are too close to distinguish clearly, thereby demonstrating the high degree of repeatability of the measurement. Each point represents ten seconds of data. The shape of this curve can be compared to FIG. 21. For this delay time τ, the point of maximum sensitivity should occur at 48 ml/min, which is in good agreement with the data.

### Example IV

To demonstrate sensitivity and repeatability over a larger flow rate range, a set of four ranges are defined as shown in Table I, as follows:

TABLE I

| | Center of | | | | | Scans per |
|---|---|---|---|---|---|---|
| Range | Range | Delay Time | | Repeat Time | | 10 sec |
| 1 | 10 ml/min | 120 | ms | 1 | s | 10 |
| 2 | 20 ml/min | 60 | ms | 0.5 | s | 20 |
| 3 | 40 ml/min | 30 | ms | 0.25 | s | 40 |
| 4 | 80 ml/min | 15 | ms | 0.125 | s | 80 |

The center-of-range volume flow rates (given in milliliters per minute) in Table I meet the condition for maximum sensitivity for the corresponding delay time τ. The repeat times are chosen long enough so that the first 90° RF pulse occurs when the coil volume 142 (FIGS. 15-17) is nearly completely refilled with magnetized fluid. The column labeled Scans gives the number of two pulse sequences that can be completed in 10 seconds. At higher flow rates, the repeat time can be shorter, so the number of pulse sequences that can be collected in ten seconds is longer.

The FID signal amplitude ratio R versus flow rate Q for the overlapping flow rate ranges are shown in FIG. 26. The four lines in each range, which are too close to each other to distinguish clearly, correspond to four separate data sets taken over a several hour period. The 90° RF pulse duration is close to 10 μs and the Larmor frequency is 17.996 MHz. The flow rates were measured with a Coriolis flow meter.

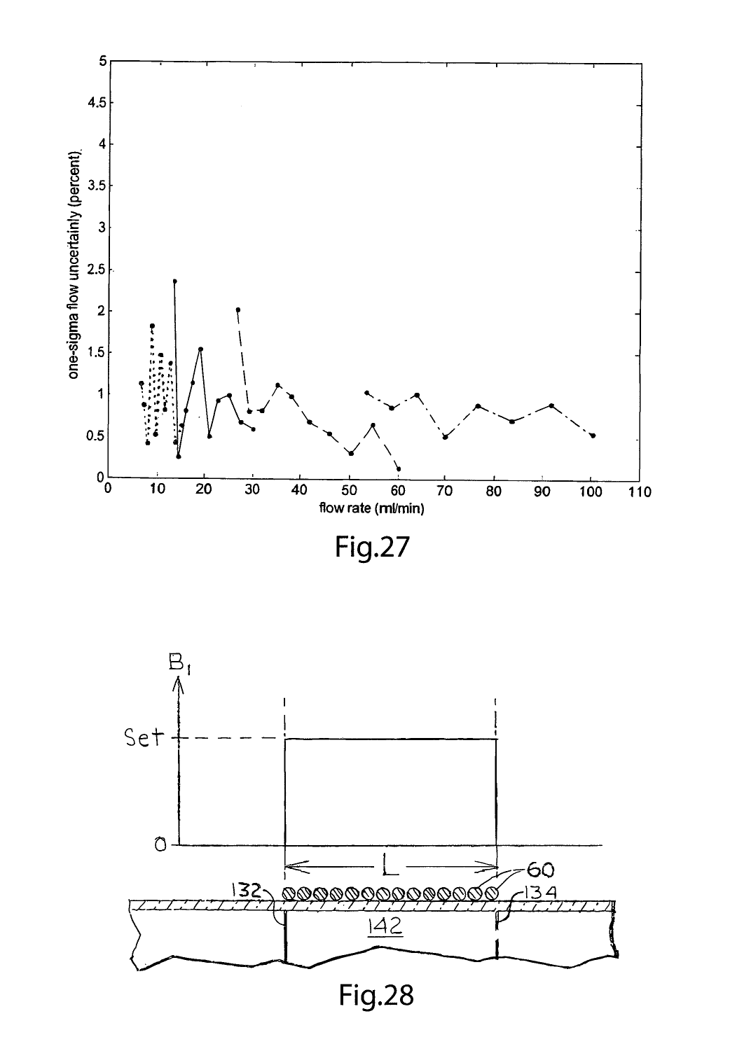

From the variability of the results shown in FIG. 26, the flow rate repeatability can be computed and is shown in FIG. 27, where the range 1 is dotted line, range 2 is solid line, range 3 is dashed line, and range 4 is dash-dotted line. These graphs are percentage-of-point repeatability values, not percent full-scale, so the values are quite good. The averaged one-sigma flow rate uncertainty is 1.0% from 6.7 ml/min to 100 ml/min. (The fluctuations about 1.0% in FIG. 27 are to be expected when each value is estimated from four samples.) At the lowest flows, there may be a contribution to the uncertainty from the accuracy of the Coriolis flow meter/controller.

At flow rates above 100 ml/min, the repeatability degrades in this example, because of flow instability (incipient turbulence) in the pre-magnetizer. Flow instability causes fluctuations in transit time of fluid elements moving through the pre-magnetizer, which, in turn, will cause spatial and temporal fluctuations of the magnetization entering the coil volume 142 (FIGS. 15-17). At 100 ml/min, the Reynolds number in the coil volume 142 is 530. The onset of turbulence occurs in cylindrical pipes at a Reynolds number of 2,000. However, because of an abrupt change in diameter of the sample tube 40 from the inlet end 50 to the enlarged portion 58 at the start of the pre-magnetizer zone 42 (see FIGS. 6 and 7) that was used in this example, some instability at some lower flow rates occurred, which may be improved with better tube fabrication.

While the sensitivity of the flow rate measurement with the apparatus and method discussed above is good, it can be improved further by shaping the RF magnetic field B₁ produced by the coil 16. Referring again to the idealized illustrations of the apparatus and flow measuring process in FIGS. 15-17, the coil volume 142 in which the fluid 120 is exposed to the transverse RF magnetic field B₁ during the application of the 90° RF pulse is illustrated as being quite distinctly defined between the end boundaries 132, 134, which correspond to the opposite ends of the coil 16. If that was the case, the amplitude of the RF magnetic field B₁ over the length L of the coil volume 142 would have to be constant from one end 132 to the other end 134, and then drop abruptly to zero outside each end 132, 134, as illustrated in FIG. 28. In other words, ideally, the RF magnetic field B₁ would be uniform in magnitude throughout the coil volume 142 and would not extend outside the coil volume 142, so that all of the fluid within the coil volume 142 would be activated by an RF pulse from the coil 60 and none of the magnetized fluid outside the coil volume 142 would be activated by the coil 60.

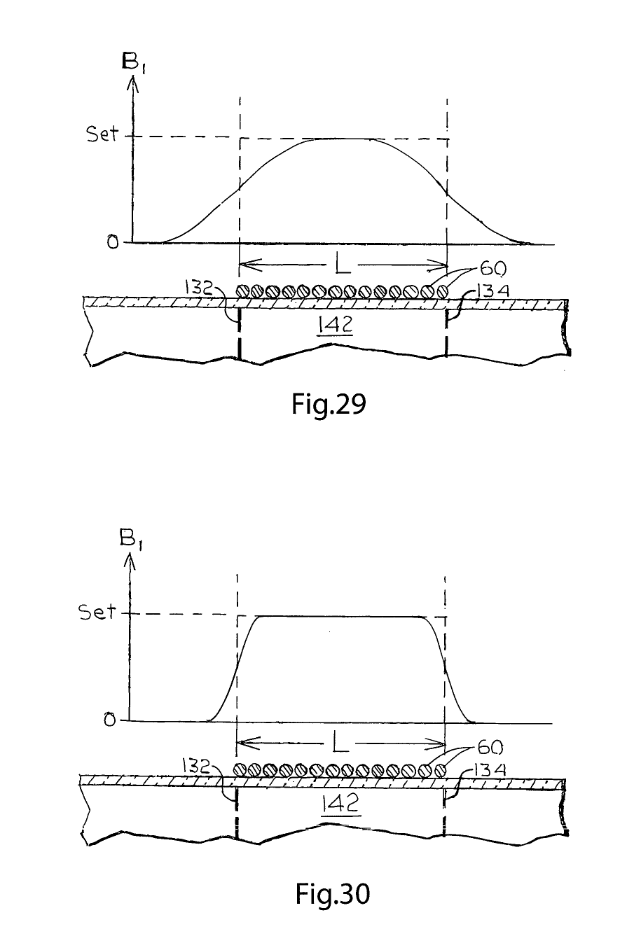

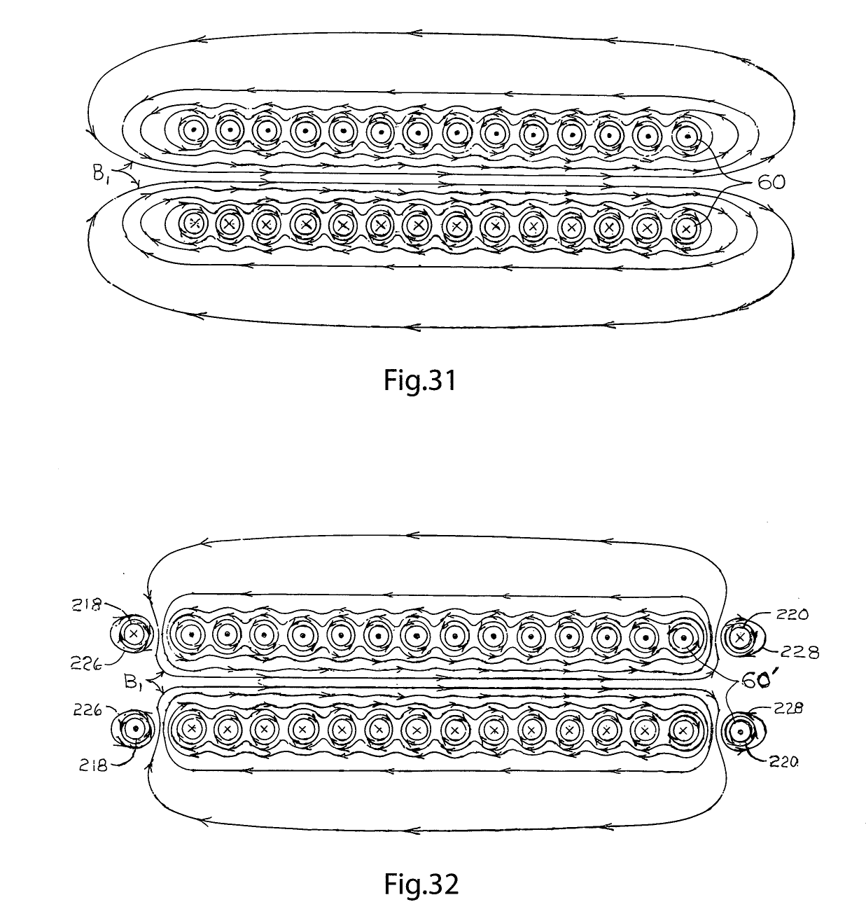

However, because of the shape of the RF magnetic field B₁ produced by a conventional coil, such as the coil 60, as illustrated diagrammatically, for example, in FIG. 31, extends beyond the length L of the coil 16 and is not uniform in the end zones, the actual strength (magnitude) profile of the RF magnetic field B₁ produced by the coil 60 may be closer to that illustrated in FIG. 29. Consequently, the actual volume V of the fluid influenced by the RF magnetic field B₁ from which the NMR signals are obtained might not be exactly the same as the idealized coil volume 142 depicted in the illustrations in FIGS. 15-19, and the size of the flow channel defined by the RF magnetic field B₁ that contains that actual volume V of fluid influenced by the RF magnetic field B₁ may not be quite the same length L as the length of the coil 60. Therefore, the length L and/or volume V might not be amenable to precise determination for direct calculation of flow velocity ν and/or volume flow rate Q. However, as long as the coil 60, the parameters of the RF electric pulse used to drive the coil 60, and the geometry of the flow channel (e.g., the relevant portion of the tube 40 or any other flow channel structure that contains the fluid influenced by the RF magnetic field B₁) all remain the same, i.e., are constant, then the input variables for determining flow velocity ν and/or flow rate Q in that particular system are the ratio R and the delay time τ. Consequently, for a particular delay time T as discussed above, the flow velocity ν and flow rate Q are functions of the ratio R, and accurate flow rates of the fluid are obtainable based on the ratio R as described above and illustrated, for example, in FIGS. 25 and 26. Calibration with known flow rates or with other instruments may be helpful for accurate quantifications of flow measurements, which is common with flow meters of all kinds.

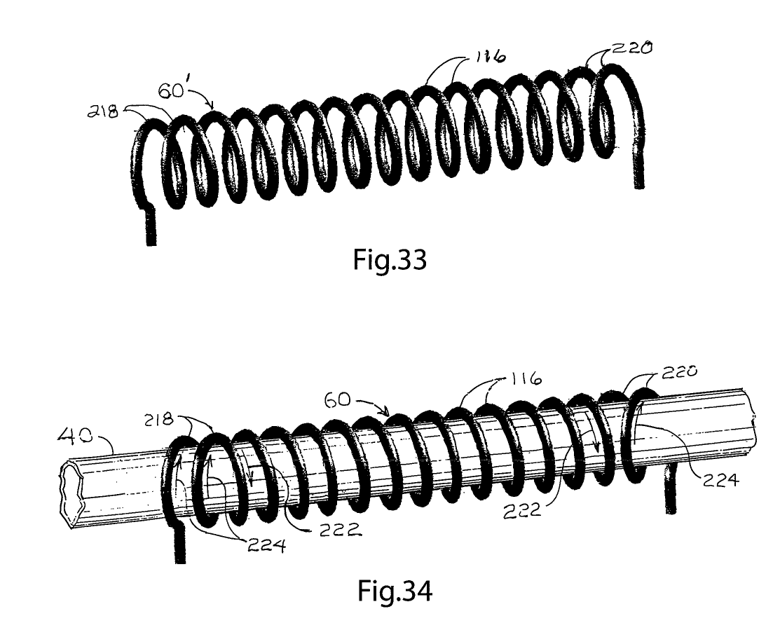

While the sensitivity of the flow rate Q measurements with the apparatus and methods described above is good, it can be improved further by shaping the RF magnetic field B₁ produced by the coil 60 to conform it more closely to the idealized profile in FIG. 28. For example, a modified coil 60′, as shown in FIG. 33, has most of its length made with normal loops 116 in the same spiral (angular) direction as each other, but it also has one or more end loops 218, 220 on each end of the coil 60′ bent or turned to spiral in the opposite angular direction from the normal loops 116. Therefore, when the modified coil 60′ is positioned on the NMR sample tube 40, as shown in FIG. 34, the electric current flows in one spiral (angular) direction, as indicated by arrows 222, in the normal loops 116 around the tube 40 for most of its length, but it flows in the opposite spiral (angular) direction, as indicated by arrows 224, in the end loops 218, 220. These end loops 218, 220, with the electric current flowing in the opposite direction 224, as compared to the current flow direction 222 in the normal loops 116, create local magnetic fields 226, 228 at the ends of the coil 60′ that oppose the end areas of the RF magnetic field B₁ in a manner that shapes field B₁ to form more tightly around the ends of the coil 60′ and to attenuate the axial extension of the magnetic field B₁ beyond the ends of the coil 60′, as illustrated diagrammatically, for example, in FIG. 32. Therefore, the strength (magnitude) of the RF field B₁ produced by the modified coil 60′, as shown, for example, in FIG. 30, is closer to the idealized B₁ profile in FIG. 28 than is the B₁ profile in FIG. 29. Consequently, the modified coil 60′ with the reversed flow end loops 218, 220 in FIGS. 32 and 34 increases sensitivity of the example NMR apparatus and methods described above. There are other methods and/or apparatus that can be used to tighten the RF magnetic field B₁ or to attenuate it in the axial direction outward from the coil 60, such as varying the distance between some of the loops, using multiple coils, or using more than one layer of turns over a portion of the coil.

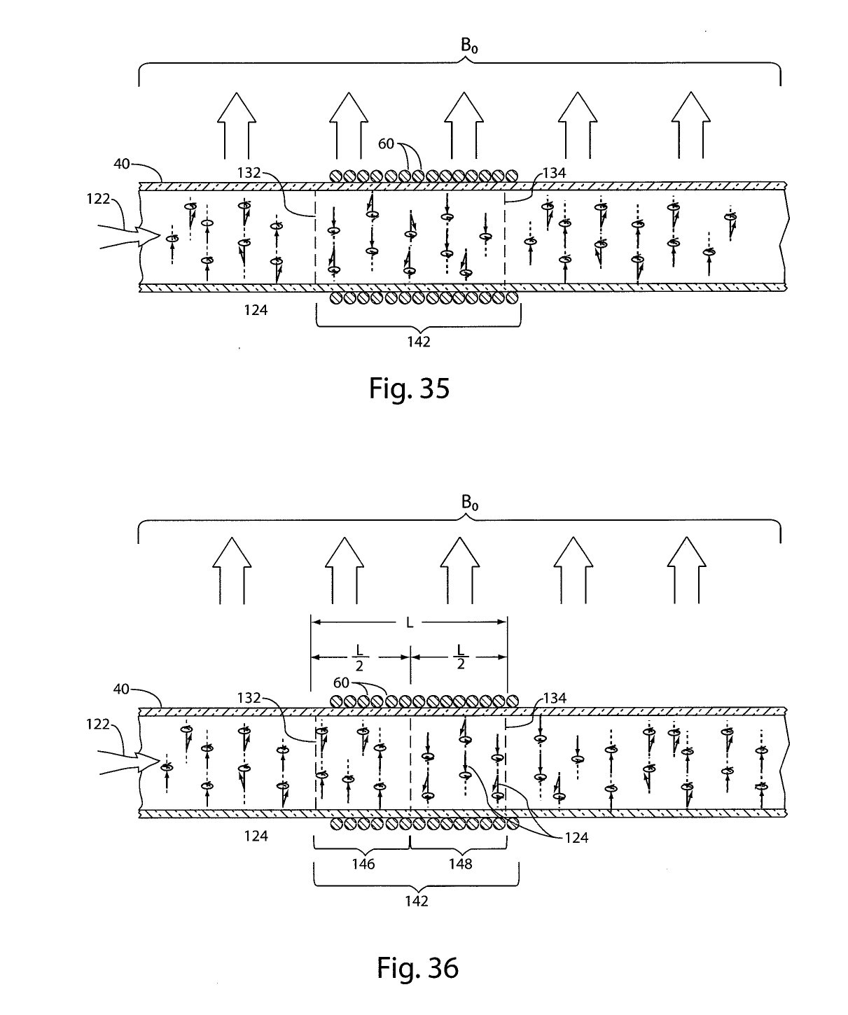

As mentioned above, errors in the duration of the 90 degree pulses in the 90-τ-90 pulse sequence described above for the coil depletion method of measuring flow, i.e., a pulse that is too long or too short to rotate the magnetic field of the material M₀ into the 90 degree plane that is orthogonal to the direction of the analytical magnetic field B₀, will result in variations in the NMR signals, thus errors in the flow measurements. The zeroing, including auto-zeroing, described above is one way to minimize or eliminate those errors. An alternative method of measuring flow, which can also be performed with the apparatus and systems described above, is less sensitive to pulse duration errors. In this alternative method, sometimes referred to herein as the bridge method, flow rate is not found by the ratio R between the amplitude of the second FID signal to the amplitude of the first FID signal, as was described above for the coil depletion method. Instead, referring to FIGS. 35-37, a different pulse sequence, i.e., 180τ′-90 pulse sequence, is used, where r′ is the time it takes for the fluid flowing in the sample tube 40 to replace one-half 146 of the coil volume 142 with fresh, magnetized fluid after a first 180 degree pulse. That time τ′ can be found where the FID signal amplitude detected by the coil 60 after the 90 degree pulse is zero, as will be explained in more detail below. Once the time τ′ is found, the flow rate can be calculated from the known volume V of fluid in one-half of the coil volume 142 divided by the time τ′. Similarly, if the diameter of the sample tube 40 is constant throughout the coil length L, flow velocity ν of the fluid can be calculated by dividing one-half of the length L of the coil 60 by the time τ′.

As explained above in relation to the coil depletion method, the fluid in the sample tube 40 is initially magnetized by the pre-magnetizer field B_{P} and then by the analytical field B₀ so that it is magnetized to be generally aligned with the analytical field B₀, as indicated diagrammatically by the alignment of the precessing nuclear magnetic moments 124 in idealized illustration in FIG. 14. Therefore, when a 180 degree RF pulse from the coil 60 at the Larmor frequency is applied to the fluid in the coil volume 142, the precessing nuclear magnetic moments 124 in the coil volume 142 are inverted, as illustrated in the idealized diagrammatical representation of inverted nuclear magnetic moments 124 in FIG. 35.

Then, continuing with the idealized, plug flow, i.e., assumed uniform flow velocity profile, illustration in FIG. 36, at a time τ′ after the 180 degree pulse, one-half of the coil volume 142 is refilled by the flowing fluid with fresh, magnetized fluid, as illustrated by the nuclear magnetic moments 124 aligned with the analytical field B₀ filling the first half 146 of the coil volume 142. The inverted, precessing, nuclear magnetic moments 124 still fill the second half 148 of the coil volume 142, as also illustrated in FIG. 36.

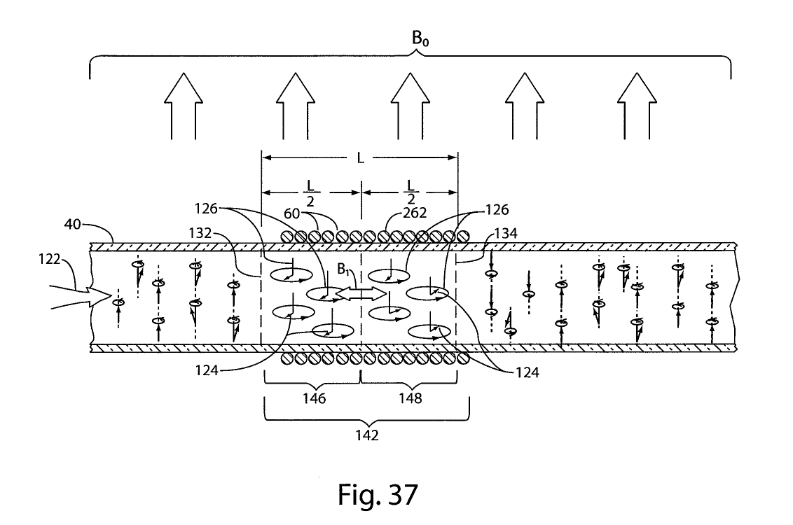

Therefore, when a 90 degree RF pulse from the coil 60 is applied to the fluid in the coil volume 142 at that time τ′ after the 180 degree RF pulse, the precessing nuclear magnetic moments 124 of the fresh, magnetized fluid in the first half 146 of the coil volume 142 are rotated to the 90 degree plane 126, as shown diagrammatically in FIG. 37, as the RF magnetic field B₁ induced by the 90 degree RF pulse imposes coherent phase on them in the same manner as described above for the coil depletion method. At the same time, the 90 degree RF pulse also rotates the inverted nuclear magnetic moments 124′ in the fluid that still occupies the second half 148 of the coil volume 142 back down to the 90 degree plane 126 and imposes coherent phase on them, as also illustrated in FIG. 37.

However, as also shown in FIG. 37, the coherently precessing nuclear magnetic moments 124′ in the second half 148 of the coil volume 142 are 180 degrees out of phase with the coherently precessing nuclear magnetic moments 124 in the first half 146 of the coil volume 142, as indicated diagrammatically by the nuclear magnetic moment vector arrows 124, 124′, respectively, in FIG. 37 pointing in opposite directions from each other. Therefore, the FID from the fluid in the first half 146 and the FID from the fluid in the second half 148 of the coil volume 142 cancel each other out, and the net FID signal from the coil volume 142 is zero. Consequently, when the delay time τ′ between the 180 degree RF pulse and the 90 degree RF pulse is the time it takes for the flowing fluid to replace one-half of the fluid in the coil volume 142 with fresh magnetized fluid, the net FID signal after the 90 degree RF pulse will be zero. Further, once that correct delay time τ′ is found, it can be used to calculate the volume flow rate Q by dividing one-half of the volume V, i.e., one-half of the coil volume 142, by the time τ′. Therefore, with this bridge method of determining flow rate Q, the flow rate Q is a function of the delay time τ′ that results in the FID signal after the 90 degree RF pulse in the sequence being zero, i.e., no detectable FID signal after the 90 degree RF pulse. The correct delay time to result in no FID signal after this 180τ′-90 pulse sequence can be found iteratively by trying different τ′ values is successive sequences of the 180°-τ′90° RF pulses as described above until the net FID signal after the 90° RF pulse in a sequence is zero. Persons skilled in the art know how to converge iterative values quickly to the target value, so an iterative process of finding the correct value for τ′ can be done very quickly. Of course, fluid velocity ν can also be found by dividing one-half of the length L of the coil volume 142 by the correct time τ′ and/or by the direct relationship between flow velocity ν and flow rate Q, as described above.

Again, as discussed above in relation to the coil depletion method of finding flow rate and/or flow velocity, in the real world, the RF magnetic field B₁ does not begin and end abruptly at the ends of the coil 60 as neatly as illustrated in the idealistic figures and simplified explanation above. Therefore, the length L of the constant volume flow channel in which the fluid is influenced by the RF magnetic field B₁ may not be exactly the same as the length of the coil 60, and the constant volume flow channel in which the fluid is influenced by the RF magnetic field B₁ may not be exactly the same volume as the idealized coil volume 142 depicted in FIGS. 35-37, although they will be close, so direct flow velocity ν and/or flow rate Q calculations using the length of the coil 60 or the coil volume 142 for determining the one-half volume V value or the one-half L value might have some inaccuracy. However, with calibration or an empirically determined correction factor, the flow velocity ν and/or flow rate Q determinations with this method can be accurate. Also, shaping the RF magnetic field B₁, for example as shown and described above in relation to FIGS. 28-34, can contribute to increased accuracy and sensitivity.

As also mentioned above, in addition to the flow metering and controlling applications, the apparatus and methods described herein also have other NMR analytical applications for fluids. Three major approaches in which the apparatus and methods described herein are useful include: (i) NMR signal intensity; (ii) spin-lattice relaxation time T₁; and (iii) spin-spin relaxation time T₂. Some example analytical applications in which one or more of the methods and apparatus described herein are useful, either alone or in combination with other instrumentations and measurements (e.g., temperature, etc.), may include: ortho concentration in liquid hydrogen, oxygen concentration in water, oxygen concentration in organic solvents, discrimination of mesophases in liquid crystals, concentration of metal ions in water, solids content and solid surface area of slurries, fat content of oil/water emulsions, quality of cooking oil, solids content of black liquor, and many others.

The words “comprise,” ‘comprises,” “comprising,” “composed,” “composes,”, “composing,” “include,” “including,” and “includes” when used in this specification, including the claims, are intended to specify the presence of state features, integers, components, or steps, but they do not preclude the presence or addition of one or more other features, integers, components, steps, or groups thereof. Also the words “maximize” and “minimize” as used herein include increasing toward or approaching a maximum and reducing toward or approaching a minimum, respectively, even if not all the way to an absolute possible maximum or to an absolute possible minimum. The term “insignificant” means not enough to make a difference in practical applications, unless the context indicates otherwise. Also, the measurements described can be repeated any number of times by allowing enough time between measurements for the fluid affected by the RF field to clear out of the coil volume 142 and then performing the measurements again, and multiple measurements can be used, if desired, to determine flow rate or rates, average flow rates, statistical flow rates, etc. Also, while the methods described above referred to NMR measurements utilizing the spins or nuclear magnetic moments of hydrogen, these NMR measurements can also be made with nuclear magnetic moments of fluorine, chlorine, and other materials having odd numbers of protons in their atomic structures.

The embodiments of the invention in which an exclusive property or privilege is claimed are defined as follows:

1. A method of determining flow rate of a fluid, comprising:
flowing the fluid through a constant volume flow channel;
obtaining a first NMR signal from the fluid in the constant volume flow channel;
continue flowing the fluid to replace some, but not all, of the fluid from which the first NMR signal was obtained in the constant volume flow channel with fluid from which the first NMR signal was not obtained;
obtaining a second NMR signal from the fluid that is then in the constant volume flow channel;
determining an amplitude of the first NMR signal and an amplitude of the second NMR signal; and
determining the flow rate of the fluid as a function of a ratio of the amplitude of the second NMR signal to the amplitude of the first NMR signal.

2. The method of claim 1, including obtaining the first and second NMR signals by:
magnetizing the fluid in a analytical magnetic field direction;
applying a first RF magnetic field pulse to the magnetized fluid in the constant volume flow channel in a direction at least a component of which is orthogonal to the analytical magnetic field direction, and detecting the NMR signal that emanates from the fluid in the flow channel after application of the first RF magnetic field pulse; and
after a delay time sufficient for some, but not all, of the fluid from which the first NMR signal was obtained to flow out of the constant volume flow channel and to be replaced by fluid that has not been influenced by the first RF magnetic field pulse, applying a second RF magnetic field pulse in the same direction as the first RF magnetic field pulse, and detecting the NMR signal that emanates from the fluid in the constant volume flow channel after the application of the second RF magnetic field pulse.

3. The method of claim 2, wherein the NMR signals are FID signals.

4. The method of claim 3, wherein the first and second RF magnetic pulses are 90° RF pulses.

5. The method of claim 2, wherein the NMR signals are spin-echo signals.

6. The method of claim 1, wherein the first and second NMR signals are a combination of FID and spin-echo signals.

7. The method of claim 6, wherein the first and second NMR signals are produced by a first sequence comprising a 90° RF pulse, a first time delay, and a 180° RF pulse followed after a second time delay by a second sequence comprising another 90° RF pulse, another time delay equal to the first time delay, and another 180° RF pulse, wherein the first time delay is shorter than the second time delay.

8. The method of claim 1, wherein the constant volume flow channel is a portion of an elongated tube.

9. The method of claim 8, wherein the constant volume flow channel portion of the elongated tube is defined by the portion of the tube in which fluid flowing in the tube is influenced by the RF magnetic field pulses.

10. The method of claim 2, wherein the delay time is sufficient for 20% to 80% of the fluid from which the first NMR signal was obtained to flow out of the constant volume flow channel and to be replaced by fluid that has not been influenced by the first RF magnetic field pulse.

11. The method of claim 4, including producing each of the first and second 90° RF pulses by applying a RF electrical signal to a coil positioned adjacent the constant volume flow channel for a sufficient pulse time duration to reorient the magnetization of the magnetized fluid to a plane orthogonal to the direction of the analytical magnetic field.

12. The method of claim 11, including performing a zeroing operation to set the pulse time duration while the fluid is flowing through the constant volume flow channel by temporarily setting the delay time between the first and second RF pulses to be short enough that no more than an insignificant amount of fluid flows out of the constant volume flow chamber between the first and second pulses, measuring the amplitude of the second NMR signal, and, if the amplitude of the second NMR signal is not zero, adjusting the pulse time duration and repeating the first and second RF pulses until the amplitude of the second NMR signal is zero.

13. The method of claim 12, temporarily setting the delay time between the first and second pulses to a value in a range of 0.1 to 2.0 milliseconds.

14. The method of claim 2, including using different time delays between the first and second RF magnetic field pulses for different flow rate ranges.

15. The method of claim 14, including extending flow rate measuring turn-down by using multiple time delays between first and second RF magnetic field pulses for overlapping flow rate ranges.

16. The method of claim 2, including magnetizing the fluid by flowing the fluid through a pre-magnetizer zone comprising a pre-magnetizer magnet assembly to pre-magnetize the fluid and then flowing the fluid through a analytical zone comprising a analytical magnet assembly with a more uniform magnetic field than the magnetic field of the pre-magnetizer magnet assembly to homogenize the magnetization of the fluid in the analytical magnetic field direction.

17. The method of claim 16, including providing a dwell time of the fluid in the pre-magnetizer zone sufficient to achieve 60 to 99 percent magnetization of the fluid.

18. The method of claim 16, including providing a dwell time of the fluid in the pre-magnetizer zone sufficient to achieve 60 to 80 percent magnetization of the fluid.

19. The method of claim 16, including providing a dwell time of the fluid in the pre-magnetizer zone in a range of 0.1 to 3.0 times the spin-lattice relaxation time of the nuclear magnetic moments in the fluid.

20. The method of claim 16, including providing a dwell time of the fluid in the pre-magnetizer zone in a range of 0.5 to 1.5 times the spin-lattice relaxation time of the nuclear magnetic moments in the fluid.

21. The method of claim 16, wherein the pre-magnetizer magnet assembly comprises a Halbach cylinder type magnet assembly.

22. The method of claim 16, wherein the analytical magnet assembly comprises a pseudo-Helmholtz magnet assembly.

23. The method of claim 16, wherein the pre-magnetizer magnet assembly comprises a Halbach cylinder type magnet assembly and the analytical magnet assembly comprises a pseudo-Helmholtz magnet.

24. The method of claim 11, wherein the constant volume flow channel comprises a portion of an elongated tube, and the coil comprises an electrically conductive wire wound helically around the constant volume flow channel portion of the elongated tube.

25. The method of claim 24, wherein at least one loop on each end of the coil is wrapped around the constant volume flow channel portion of the tube in a direction that directs electric current flow oppositely around the constant volume flow channel portion of the tube as compared to the current flow direction in the primary loops.

26. A method of determining flow rate of a fluid, comprising:
flowing the fluid through a constant volume flow channel and determining the time that it takes the flowing fluid to replace one-half of the fluid in the constant volume flow channel by magnetizing the flowing fluid and applying successive sequences of a 180° RF magnetic pulse followed by a time delay and then a 90° RF magnetic pulse, wherein the 180° and 90° RF magnetic pulses are applied in a direction at least a component of which is orthogonal to the direction of the magnetization of the flowing fluid, until no FID signal is detectable from the fluid in the constant volume flow channel after the 90° RF magnetic pulse; and
determining the flow rate of the fluid as a function of the time delay found to result in no detectable FID signal from the fluid in the constant volume flow channel after the 90° RF magnetic pulse.

27. The method of claim 26, wherein the flow rate of the fluid is one-half of the volume of the constant volume flow channel divided by the time delay found to result in no detectable FID signal from the fluid in the constant volume flow channel after the 90° RF magnetic pulse.

28. Apparatus for creating and NMR signals in a flowing fluid, comprising:
a pre-magnetizer zone comprising a Halbach cylinder type magnet for applying a pre-magnetizer magnetic field to the flowing fluid adjacent a analytical magnetic assembly for applying a analytical magnetic field to the flowing fluid;
a sample tube extending through the pre-magnetizer magnetic field and through the analytical magnetic field for conducting the flowing fluid through the pre-magnetizer magnetic field and through the analytical magnetic field to magnetize the flowing fluid; and
a coil positioned adjacent the tube in the analytical magnetic field for applying RF magnetic pulses to the magnetized flowing fluid in a direction at least a component of which is orthogonal to the direction of the analytical magnetic field.

29. The apparatus of claim 28, wherein the analytical magnetic assembly comprises a pseudo-Helmholtz magnet assembly comprising two cylindrical disc-shaped permanent magnets magnetized in the direction of the cylinder axes of the cylindrical disc magnets and positioned in axial alignment with each other and spaced a distance apart from each other that maximizes uniformity of the analytical magnetic field between them.

30. The apparatus of claim 28, wherein the Halbach cylinder type magnet includes an assembly of four elongated bar magnets, each of which is magnetized in a direction transverse to its longitudinal axis, and wherein said bar magnets are positioned in close proximity to each other in a cross-sectional cross configuration that leaves a common space between all of them and with each diagonally opposite pair of the bar magnets oriented with their direction of magnetization in common with each other and orthogonal to the direction of magnetization of the other pair of the bar magnets.

31. The apparatus of claim 28, wherein:
the Halbach cylinder type magnet includes an assembly of four elongated bar magnets, each of which is magnetized in a direction transverse to its longitudinal axis, and wherein said bar magnets are positioned in close proximity to each other in a cross-sectional cross configuration that leaves a common space between all of them and with each diagonally opposite pair of the bar magnets oriented with their direction of magnetization in common with each other and orthogonal to the direction of magnetization of the other pair of the bar magnets;
the analytical magnetic assembly comprises a pseudo-Helmholtz magnet assembly comprising two cylindrical disc-shaped permanent magnets magnetized in the direction of the cylinder axes of the cylindrical disc magnets and positioned in axial alignment with each other and spaced a distance apart from each other that maximizes uniformity of the analytical magnetic field between them;
the sample tube extends longitudinally through the common space between the four bar magnets of the Halbach cylinder type magnet assembly and between the cylindrical disc magnets of the pseudo-Helmholtz magnet assembly in a manner that intersects the common longitudinal axis of the cylindrical disc magnets; and
the coil is positioned around the sample tube at a location between the spaced apart cylindrical disc magnets where the sample tube intersects the common longitudinal axis of the cylindrical disc magnets of the pseudo-Helmholtz magnet assembly.

32. The apparatus of claim 31, wherein one or more of the cylindrical disc magnets is shimmed to maximize uniformity of the analytical magnetic field at the location of the coil.

33. The apparatus of claim 32, wherein the cylindrical disc magnet is shimmed by a material that affects the analytical magnetic field positioned on the external end surface of the cylindrical disc magnet.

34. Magnet apparatus for creating a uniform permanent magnetic field, comprising two cylindrical disk-shaped permanent magnets that are magnetized in the direction of the cylinder axes of the cylindrical permanent disc magnets and positioned in co-axial alignment with each other and spaced a distance apart from each other that maximizes uniformity of the analytical magnetic field between the two cylindrical permanent disc magnets.

35. The permanent magnet apparatus of claim 34, wherein one or more of the cylindrical disc-shaped permanent magnets is shimmed to maximize uniformity of the magnetic field between them.

36. The permanent magnet apparatus of claim 35, wherein the cylindrical disc-shaped permanent magnet is shimmed by a material that affects the analytical magnetic field positioned on the external end surface of the cylindrical disc-shaped permanent magnet.

37. The permanent magnet apparatus of claim 36, wherein the cylindrical disc-shaped magnet is shimmed with a steel ball attached to the external surface.

38. A method of shimming magnet apparatus that includes two cylindrical disk-shaped permanent magnets that are magnetized in the direction of the cylinder axes of the cylindrical permanent disc magnets and positioned in co-axial alignment with each other and spaced a distance apart from each other that maximizes uniformity of the analytical magnetic field between the two cylindrical permanent disc magnets in order to enhance uniformity of the magnetic field, comprising:
positioning one or more shims on the external surface of one or more of the cylindrical disk-shaped permanent magnets that is opposite the internal face of the cylindrical disk-shaped permanent magnet that is juxtaposed to the other cylindrical disk-shaped permanent magnets.

39. The method of claim 38, including:
mapping at least a portion of the magnetic field between the two cylindrical disk-shaped permanent magnets by positioning a Hall magnetometer at a plurality of locations in the space between the two cylindrical disk-shaped permanent magnets and measuring and recording the magnetic field strength measured by the Hall magnetometer at each of the locations along with information that designates the spatial relationships of each of the locations to each other and to the cylindrical disk-shaped permanent magnets; and
placing one or more shims on the external surface of one or more of the cylindrical disk-shaped permanent magnets to minimize inhomogeneities in the magnetic field found by mapping the magnetic field with the Hall magnetometer.

40. The method of claim 39, including determining where to place the one or more shims empirically.

41. The method of claim 39, including:
determining characteristics and locations on one or more of the external surfaces for one or more shims with a magnetic field computation program using parameters that characterize and quantify the two cylindrical disk-shaped permanent magnets and the magnetic field produced by them as adjusted by the mapped magnetic field information that will minimize inhomogeneities in the magnetic field; and
placing one or more shims with the characteristics indicated by the magnetic field computation program on the one or more external surfaces at the location or locations as determined with the use of the field computation program.

42. A method of obtaining a NMR signal from a flowing fluid, comprising:
magnetizing the fluid by flowing the fluid through a pre-magnetizer magnetic field created by a Halbach-cylinder type magnet assembly positioned adjacent a analytical magnetic field;
flowing the fluid from the pre-magnetizer magnetic field into the analytical magnetic field;
applying a RF magnetic field pulse to the fluid in the analytical magnetic field in a direction at least a component of which is orthogonal to the direction of the analytical magnetic field; and
detecting a NMR signal from the fluid to which the RF magnetic field was applied.

43. The method of claim 42, including creating the analytical magnetic field with a pseudo-Helmholtz type permanent magnet assembly comprising two cylindrical disk-shaped permanent magnets that are magnetized in the direction of the cylinder axes of the cylindrical disc-shaped permanent magnets and positioned in co-axial alignment with each other and spaced a distance apart from each other that maximizes uniformity of the analytical magnetic field between the two cylindrical disc-shaped permanent magnets.

44. The method of claim 43, including flowing the fluid through a tube that extends through the Halbach cylinder type pre-magnetizer assembly and through the space between two cylindrical disc-shaped permanent magnets for magnetizing the fluid;

45. The method of claim 44, wherein the tube intersects the axis that is common to the two cylindrical disc-shaped permanent magnets and a coil is positioned adjacent the tube at the location where the tube intersects the axis for imparting the RF magnetic field pulse to the fluid flowing in the tube.

46. The method of claim 45, including obtaining the NMR signal from the fluid with the coil after the RF magnetic field pulse has been applied to the fluid.

47. Apparatus for obtaining a NMR signal from a flowing fluid, comprising:
means for magnetizing the fluid by flowing the fluid through a pre-magnetizer magnetic field created by a Halbach-cylinder type magnet assembly positioned adjacent a analytical magnetic field;
means for flowing the fluid from the pre-magnetizer magnetic field into the analytical magnetic field;
means for applying a RF magnetic field pulse to the fluid in the analytical magnetic field in a direction at least a component of which is orthogonal to the direction of the analytical magnetic field; and
means for detecting a NMR signal from the fluid to which the RF magnetic field was applied.

48. The apparatus of claim 47, wherein the means for creating the analytical magnetic field includes a pseudo-Helmholtz type permanent magnet assembly comprising two cylindrical disk-shaped permanent magnets that are magnetized in the direction of the cylinder axes of the cylindrical disc-shaped permanent magnets and positioned in co-axial alignment with each other and spaced a distance apart from each other that maximizes uniformity of the analytical magnetic field between the two cylindrical disc-shaped permanent magnets.

49. The apparatus of claim 48, wherein the means for flowing the fluid through the pre-magnetizer and analytical magnetic fields includes a tube that extends through the Halbach cylinder type pre-magnetizer assembly and through the space between two cylindrical disc-shaped permanent magnets for magnetizing the fluid;

50. The apparatus of claim 49, wherein the tube intersects the axis that is common to the two cylindrical disc-shaped permanent magnets and a coil is positioned adjacent the tube at the location where the tube intersects the axis for imparting the RF magnetic field pulse to the fluid flowing in the tube.

51. The method of claim 50, wherein the means for detecting a NMR signal from the fluid to which the RF magnetic field was applied includes the coil.
